(19) United States
(12) Patent Application Publication
(10) Pub. No.: US 2026/0057127 A1
(43) Pub. Date: Feb. 26, 2026

(54) DESIGN METHOD FOR BLADE WITH ORIENTATION STRUCTURES, BLADE AND PERFORMANCE TEST METHOD FOR BLADE

(71) Applicant: Pinliang LIU, Fangshan District (CN)

(72) Inventor: Pinliang LIU, Fangshan District (CN)

(21) Appl. No.: 18/810,571

(22) Filed: Aug. 21, 2024

(51) Int. Cl. G06F 30/17; G01M 15/14

(52) U.S. Cl. CPC G06F 30/17; G01M 15/14

(57) ABSTRACT

A design method for a blade with orientation structures, a blade and a performance test method for a blade are provided, which relate to the technical field of blade design, and are universal to blades whose parameters are completely or partially known. In the design method, orientation awls are provided at a trailing edge of a blade from a variable-pitch propeller; orientation awls are provided at a trailing edge of a blade from a fixed-pitch propeller or a fan blade from a jet engine, and orientation grooves are provided on a back of the blade. Meanwhile, during providing orientation awls for either blade, the blade is stretched in a chord direction to ensure that an area of a pressure surface of a modified blade is equal to an area of a pressure surface of its original.

### TECHNICAL FIELD

The present disclosure relates to the field of blade structure design, in particular to a design method for a blade with orientation structures, a blade and a performance test method for a blade.

### BACKGROUND

Propellers and fans are widely used in various fields. Based on the existing performance of the fan of the turbofan engine and the propeller in service, the present disclosure is intended to provide orientation structures which can further enhance the efficiency and are universal and designed integrally with the blade, and incidentally, and further provides a method for detecting the performance of the propeller, which can be used to verify the orientation structures.

### SUMMARY

The embodiments aim to provide a design method for a blade with orientation structures, a blade and a performance test method for a blade, so as to solve the problems existing in the prior art. The design method is universal to blades with various structures, and the performance of a propeller or a fan with modified blades with orientation structures designed based on the method can be obviously improved.

In order to achieve the above objective, the present disclosure provides the following schemes. The present disclosure provides a design method for a blade with orientation structures,

for a criterial blade with known design parameters, the design method including:
S11, cutting materials at a trailing edge of the criterial blade from a fixed-pitch propeller to form orientation awls to obtain a modified blade, or cutting materials at a trailing edge of the criterial blade from a variable-pitch propeller under a pitch lᵥ in a cruising state to form orientation awls to obtain a modified blade; and
S12, stretching the blade with the orientation awls in a chord direction to obtain a modified blade, where an area of a pressure surface of the modified blade is equal to an area of a pressure surface of the criterial blade in Step S11; or
for a criterial blade with unknown design parameters, the design method including:
S21, calculating a chordwise stretching coefficient of the criterial blade according to an area of a pressure surface to be cut required for forming orientation awls;
S22, stretching the criterial blade in a chord direction according to the chordwise stretching coefficient to obtain a stretched blade; and
S23, cutting materials at a trailing edge of the stretched blade from a fixed-pitch propeller to form the orientation awls to obtain a modified blade, or cutting materials at a trailing edge of the stretched blade from a variable-pitch propeller under a pitch lᵥ in a cruising state to form the orientation awls to obtain a modified blade.

In some embodiments, steps of formation of the orientation awls by cutting in Step S11 and Step S23 include:

from an axial perspective, creating (m+1) circular-arc awl-groove benchmark surfaces that are coaxial with a rotational shaft of the criterial blade and at equal intervals, where intersections between the (m+1) circular-arc awl-groove benchmark surfaces and the trailing edge of the criterial blade or the trailing edge of the stretched blade are awl tips of the orientation awls, a radius of one of the (m+1) circular-arc awl-groove benchmark surfaces with a smallest diameter is (1−σ)R, and an interval between adjacent circular-arc awl-groove benchmark surfaces of the (m+1) circular-arc awl-groove benchmark surfaces is μc_{f}; where m is an integer in a range

$$( \frac{σ R}{μ {c}_{f}} - 2 , \frac{σ R}{μ {c}_{f}} - 1 ] ,$$

R is a rotational radius of the criterial blade, c_{f} is a characteristic chord length of the criterial blade, μ is a ratio of the interval between the adjacent circular-arc awl-groove benchmark surfaces to the characteristic chord length of the criterial blade, and σ is a ratio of a radial length of a segment with the orientation awls in the criterial blade to the rotational radius R of the criterial blade; and

taking axial lines passing through the awl tips as rotational axes, a first circular-arc awl-groove benchmark surface of the (m+1) circular-arc awl-groove benchmark surfaces is rotated at an angle of γ-degree toward a blade tip, an (m+1)-th circular-arc awl-groove benchmark surface of the (m+1) circular-arc awl-groove benchmark surfaces is rotated at the angle of γ-degree toward a blade root, and each of circular-arc awl-groove benchmark surfaces between the first circular-arc awl-groove benchmark surface and the (m+1)-th circular-arc awl-groove benchmark surface is rotated at the angle of γ-degree toward the blade tip and is rotated at the angle of γ-degree toward the blade root to form an edge contour of the orientation awls; where a value of γ gradually decreases from the blade root to the blade tip.

In some embodiments, σ has a value in a range of [½, 1), μ has a value in a range of (0, ¼), and

$$\frac{R}{{c}_{f}} > 1 .$$

In some embodiments, in Step S11 and Step S23, after obtaining the edge contour of the orientation awls, the design method further includes:

blunting a connecting angle between adjacent two orientation awls of the orientation awls; where a process of blunting the connecting angle comprises: from the axial perspective, a center of a first arc where a first arc edge at one side, adjacent to the blade root, of the connecting angle is located is O₁, and a radius of the first arc is R₁, a center of a second arc where a second arc edge at an other side, away from the blade root, of the connecting angle is located is O₂, and a radius of the second arc is R₂, drawing a first circle with O₁ as a center and (R₁+R₃) as a radius, drawing a second circle with O₂ as a center and (R₂−R₃) as a radius, the first circle and the second circle intersect at a point O₃, and drawing a third circle with O₃ as a center and R₃ as a radius to obtain a blunting arc tangent to both the first arc edge and the second arc edge of the connecting angle; and

cutting the criterial blade along the edge contour of the orientation awls and a contour of blunting arcs to obtain the blade with the orientation awls.

In some embodiments, for the criterial blade from the fixed-pitch propeller with known design parameters, stretching the blade with the orientation awls in the chord direction to obtain the modified blade in Step S12 further includes:

measuring and recording an area Aₘ_{₁} of the pressure surface of the blade with the orientation awls; establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; where a positive direction of a polar angle is a rotation direction of a propeller, and in a normal direction of the rotational plane, a positive direction of the z-axis is a direction that points from the pressure surface of the criterial blade to a suction surface of the criterial blade; any point on a surface profile of the blade with the orientation awls is able to be expressed as (r, ψ, z) in cylindrical coordinates, where r, ψ, z represent a polar radius, the polar angle and a z-coordinate, respectively; and

performing an overall coordinate transformation on all profile points directly into new profile points to obtain the modified blade according to following rules: converting (r, ψ, z) into

$$( r , ( ψ - {ψ}_{0} ) ( {t}_{1} {cos}^{2} θ + {t}_{2} {sin}^{2} θ ) + \frac{z - {z}_{0}}{r} ( {t}_{1} - {t}_{2} ) sin θ cos θ + {ψ}_{0} , r ( ψ - {ψ}_{0} ) sin θ cos θ ( {t}_{1} - {t}_{2} ) + ( z - {z}_{0} ) ( {t}_{1} {sin}^{2} θ + {t}_{2} {cos}^{2} θ ) + {z}_{0} ) ;$$

where the chordwise stretching coefficient of the criterial blade is

$${t}_{1} = \frac{{A}_{c}}{{A}_{{m}_{1}}} ,$$

A_{c} is the area of the pressure surface of the criterial blade, t₂ is a stretching coefficient of the criterial blade in a thickness direction, and t₁>t₂>1, θ is an angle of attack of blade element of each of chordwise sections where profile points are located, and a tilt base point O (r, ψ₀, z₀) is a tilt base point of the chordwise section where the profile points are located.

In some embodiments, for the criterial blade from the fixed-pitch propeller with unknown design parameters, a primary treatment is first performed, the primary treatment includes:

scanning the criterial blade to obtain an external contour of the criterial blade;

establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; where a positive direction of a polar angle is a rotation direction of a propeller, and in a normal direction of the rotational plane, a positive direction of the z-axis is a direction that points from the pressure surface of the criterial blade to a suction surface of the criterial blade; and

taking chordwise sections at all characteristic positions and several ordinary positions on the criterial blade which represent an overall contour of the criterial blade, and selecting points at all characteristic positions and several ordinary positions on each of the chordwise sections which represent an overall contour of each of the chordwise sections, and expressing the points as (r, ψ, z) in cylindrical coordinates; where r, ψ, z represent a polar radius, the polar angle and a z-coordinate, respectively; where in Step S21, the chordwise stretching coefficient of the criterial blade is

$${t}_{1} = 1 + \frac{{A}_{c u t}}{{A}_{c}} ,$$

where A_{c} is the area of the pressure surface of the criterial blade, A_{cut} is an area of a pressure surface to be cut required for forming the orientation awls; and

converting the cylindrical coordinates (r, ψ, z) of points on the overall contour of each of the chordwise sections after performing the primary treatment into

$$( r , ( ψ - {ψ}_{0} ) ( {t}_{1} {cos}^{2} θ + {t}_{2} {sin}^{2} θ ) + \frac{z - {z}_{0}}{r} ( {t}_{1} - {t}_{2} ) sin θ cos θ + {ψ}_{0} , r ( ψ - {ψ}_{0} ) sin θ cos θ ( {t}_{1} - {t}_{2} ) + ( z - {z}_{0} ) ( {t}_{1} {sin}^{2} θ + {t}_{2} {cos}^{2} θ ) + {z}_{0} )$$

to obtain the stretched blade; where t₂ is a stretching coefficient of the criterial blade in a thickness direction, t₁>t₂>1, θ is an angle of attack of blade element of each of the chordwise sections where profile points are located, a tilt base point O (r, ψ₀, z₀) is a tilt base point of the chordwise section where the profile points are located, and a value of θ and a cylindrical coordinate of a point O are calculated by using the cylindrical coordinates of points where a chord is tangent to a leading edge contour and a trailing edge contour.

In some embodiments, for the criterial blade with a fixed pitch, the design method further comprises: forming m orientation grooves on a back of the modified blade on a basis of curves intersected between the m circular-arc awl-groove benchmark surfaces and the back of the modified blade, so as to make each of the curves be a bottom of a corresponding orientation groove of the m orientation grooves; wherein the m orientation grooves locate at a blade segment from a second circular-arc awl-groove benchmark surface to the (m+1)-th circular-arc awl-groove benchmark surface; each of the m orientation grooves is an arc groove with a groove depth of d, which satisfies d=λ·δₘ₋₁, where δₘ₋₁ is a blade thickness on the chordwise section where a bottom curve of an (m−1)-th orientation groove of the m orientation grooves is located, λ has a value in a range of (0, ½); a same one of the m orientation grooves has a same arc radius ρ, arc radii ranging from ρ₁ to μₘ of the m orientation grooves gradually increase from the blade root to the blade tip to form an arithmetic progression with a first term of ρ₁ and a tolerance of

$$\frac{{ρ}_{m} - {ρ}_{1}}{m - 1} ,$$

where

$$d < {ρ}_{1} < {ρ}_{m} < \frac{{μ}^{2} {c}_{f}^{2}}{8 d} + \frac{d}{2} .$$

In some embodiments, for the criterial blade from the variable-pitch propeller with known design parameters, stretching the blade with the orientation awls in the chord direction to obtain the modified blade in Step S12 further includes:

measuring and recording an area Aₘ_{₁} of the pressure surface of the blade with the orientation awls; establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; where a positive direction of a polar angle is a rotation direction of a propeller, and in a normal direction of the rotational plane, a positive direction of the z-axis is a direction that points from the pressure surface of the criterial blade to a suction surface of the criterial blade; any point on a surface profile of the blade with the orientation awls is able to be expressed as (r, ψ, z) in cylindrical coordinates, where r, ψ, z represent a polar radius, the polar angle and a z-coordinate, respectively; and

performing an overall coordinate transformation on all profile points directly into new profile points to obtain the modified blade according to following rules: converting (r, ψ, z) into

$$( r , ( ψ - {ψ}_{0} ) ( {t}_{1} {cos}^{2} θ + {sin}^{2} θ ) + \frac{z - {z}_{0}}{r} ( {t}_{1} - 1 ) sin θ cos θ + {ψ}_{0} , r ( ψ - {ψ}_{0} ) sin θ cos θ ( {t}_{1} - 1 ) + ( z - {z}_{0} ) ( {t}_{1} {sin}^{2} θ + {cos}^{2} θ ) + {z}_{0} ) ;$$

wherein the chordwise stretching coefficient of the criterial blade is

$${t}_{1} = \frac{{A}_{c}}{{A}_{{m}_{1}}} ,$$

A_{c} is the area of the pressure surface of the criterial blade, θ is an angle of attack of blade element of each of chordwise sections where profile points are located, and a tilt base point O (r, ψ₀, z₀) is a tilt base point of the chordwise section where the profile points are located.

In some embodiments, for the criterial blade from the variable-pitch propeller with unknown design parameters, a primary treatment is first performed, the primary treatment includes:

scanning the criterial blade to obtain an external contour of the criterial blade;

establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; wherein a positive direction of a polar angle is a rotation direction of a propeller, and in a normal direction of the rotational plane, a positive direction of the z-axis is a direction that points from the pressure surface of the criterial blade to a suction surface of the criterial blade; and

taking chordwise sections at all characteristic positions and several ordinary positions on the criterial blade which represent an overall contour of the criterial blade, and selecting points at all characteristic positions and several ordinary positions on each of the chordwise sections which represent an overall contour of each of the chordwise sections, and expressing the points as (r, ψ, z) in cylindrical coordinates; wherein r, ψ, z represent a polar radius, the polar angle and a z-coordinate, respectively; wherein in Step S21, the chordwise stretching coefficient of the criterial blade is

$${t}_{1} = 1 + \frac{{A}_{c u t}}{{A}_{c}} ,$$

wherein A_{c} is the area of the pressure surface of the criterial blade, A_{cut} is an area of a pressure surface to be cut required for forming the orientation awls; and

converting the cylindrical coordinates (r, ψ, z) of points on the overall contour of each of the chordwise sections after performing the primary treatment into

$$( r , ( ψ - {ψ}_{0} ) ( {t}_{1} {cos}^{2} θ + {sin}^{2} θ ) + \frac{z - {z}_{0}}{r} ( {t}_{1} - 1 ) sin θ cos θ + {ψ}_{0} , r ( ψ - {ψ}_{0} ) sin θ cos θ ( {t}_{1} - 1 ) + ( z - {z}_{0} ) ( {t}_{1} {sin}^{2} θ + {cos}^{2} θ ) + {z}_{0} )$$

to obtain the stretched blade; wherein θ is an angle of attack of blade element of each of the chordwise sections where profile points are located, a tilt base point O (r, ψ₀, z₀) is a tilt base point of the chordwise section where the profile points are located, and a value of 0 and a cylindrical coordinate of a point O are calculated by using the cylindrical coordinates of points where a chord is tangent to a leading edge contour and a trailing edge contour.

The present disclosure further provides a blade with orientation structures. The blade is manufactured according to the design method for the blade with the orientation structures described above.

The present disclosure further provides a performance test method for the blade with the orientation structures described above, including:
S1, manufacturing a zero-thrust propeller, where an angle of attack of each blade of the zero-thrust propeller is 0; each blade of the zero-thrust propeller is obtained by each blade element of the criterial blade tilting an angle of (−θ) around a corresponding tilt base point O (r, ψ₀, z₀);
S2, performing calculation according to following formulae:

$${v}_{i} = {μ}_{1} \cdot {V}_{N} sin ( θ - φ ) \qquad ( 1 )$$

where vᵢ is an induced velocity, μ₁ is a value between 0 and 1 that expresses proportion of rebound flow in a direction of vᵢ arising directly from a pressure surface of the blade element; V_{N} is a velocity of actual inflow for a N-th blade on a common propeller that is a modified propeller or a criterial propeller; and φ is an angle of the actual inflow relative to a rotational plane of the common propeller, so as to obtain

$$φ = {tan}^{- 1} \frac{{v}_{c} + {μ}_{1} sin θ ( {μ}_{2} ω r cos θ + {v}_{c} sin θ )}{{μ}_{2} ω r + {μ}_{1} cos θ ( {μ}_{2} ω r cos θ + {v}_{c} sin θ )} \qquad ( 2 )$$

where v_{c} is a velocity of axial inflow; μ₂ is a deflection coefficient of the lateral inflow, and μ₂>1; ω is a rotational angular velocity of the common propeller; and φ is an angle of the actual inflow and is expressed as a function of an angle of attack θ of the blade element, that is, φ=g(θ), so as to obtain

$${V}_{N} = \frac{{μ}_{2} ω r}{cos g ( θ ) + {μ}_{1} sin [ θ - g ( θ ) ] sin θ} \qquad ( 3 )$$

an aerodynamic force f(r) is expressed as:

$$f ( r ) = {K}_{1} \cdot \frac{1}{2} {ρ ( {V}_{N} sin α )}^{2} \cdot c \cdot dr \cdot sin α \qquad ( 4 )$$

where K₁ is a coefficient that is applied to extend an aerodynamic impact force on the pressure surface of the blade element to a comprehensive aerodynamic force on a total blade element, and K₁ is greater than 1; ρ is local air density; α is an included angle between the actual inflow and an action line for pure aerodynamic impact on the pressure surface of the blade element; the angle of attack θ of the blade element and a chord length c of the blade element are expressed as functions of a radial position r where the blade element is located, that is, θ=h(r), and c=l(r), so as to obtain

$$f ( r ) = 2 {π}^{2} ρ {K}_{1} \cdot q ( r ) \cdot l ( r ) \cdot {n}^{2} \cdot {μ}_{2}^{2} \cdot {r}^{2} d r \qquad ( 5 )$$

where

$$q ( r ) = \frac{{sin}^{3} \{ h ( r ) - g [ h ( r ) ] \}}{{\{ cos g [ h ( r ) ] + {μ}_{1} sin \{ h ( r ) - g [ h ( r ) ] \} sinh ( r ) \}}^{2}} ,$$

n is a propeller rotational speed, a relationship between an angle β and the angle of attack θ of the blade element is established by using a deflection coefficient μ₃, where β is an included angle between the aerodynamic force f(r) and an axis of rotational shaft of the common propeller, in which β=μ₃·h(r)=j(r), and propeller thrust is expressed as:

$$T = {N}_{b} {\int }_{{r}_{0}}^{R} f ( r ) \cdot cos β = 2 {π}^{2} {N}_{b} ρ {K}_{1} \cdot {μ}_{2}^{2} \cdot {n}^{2} {\int }_{{r}_{0}}^{R} q ( r ) \cdot l ( r ) \cdot cos j ( r ) \cdot {r}^{2} d r \qquad ( 6 )$$

where N_{b} is a number of blades on the propeller, r₀ is a radial position of a blade root on a propeller hub, and R is a rotational radius of the common propeller; an input power P₀ of the zero-thrust propeller is subtracted from an input power P of the modified propeller or the criterial propeller, and a pure aerodynamic drag power of the common propeller is expressed as:

$$\begin{matrix}P - {P}_{0} = ω \cdot {N}_{b} {\int }_{{r}_{0}}^{R} f ( r ) \cdot sin β \cdot r \\ = 4 {π}^{3} {N}_{b} ρ {K}_{1} \cdot {μ}_{2}^{2} \cdot {n}^{3} {\int }_{{r}_{0}}^{R} q ( r ) \cdot l ( r ) \cdot sin j ( r ) \cdot {r}^{3} d r\end{matrix} \qquad ( 7 )$$

after integration, each factor of integrands in a formula (7) is transformed and is expressed as follows: q(r) is directly expressed as a dimensionless coefficient; l(r) is converted into a length of a characteristic chord c_{f}; h(r) is converted into a characteristic angle of attack θ_{w}, and r is converted into a characteristic radius k_{f}R; making the dimensionless coefficient, c_{f}, θ_{w} and K_{f}R substitute into a formula (6) and the formula (7) to obtain following engineering formulae:

$$\{ \begin{matrix}T = K cos {θ}_{w} \cdot {c}_{f} {R}^{3} {n}^{2} \\ P - {P}_{0} = K sin {θ}_{w} \cdot 2 π {k}_{f} \cdot {c}_{f} {R}^{4} {n}^{3}\end{matrix} \qquad ( 8 )$$

where K is a propeller coefficient; on a basis of the engineering formulae (8), the pure aerodynamic drag power (P−P₀) of the common propeller is replaced by a propeller torque M, and calculation formulae for simulation is

$$\{ \begin{matrix}T = K cos {θ}_{w} \cdot {c}_{f} {R}^{3} {n}^{2} \\ M = K sin {θ}_{w} \cdot {k}_{f} \cdot {c}_{f} {R}^{4} {n}^{3}\end{matrix} \qquad ( 9 )$$

in an aspect of experimental verification, the criterial propeller with criterial blades, the modified propeller whose blades are modified by the orientation structures, and the zero-thrust propeller are driven by an identical power source, and a thrust value of each of the criterial propeller and the modified propeller under a corresponding rotational speed value of each of the criterial propeller and the modified propeller, and a power source output power value of each of the criterial propeller, the modified propeller and the zero-thrust propeller under the corresponding rotational speed value of each of the criterial propeller, the modified propeller and the zero-thrust propeller, are recorded successively to obtain data arrays for the criterial propeller, the modified propeller and the zero-thrust propeller; after recording, the thrust value of each of the modified propeller and the criterial propeller under the corresponding rotational speed value of each of the modified propeller and the criterial propeller, a power difference value between the modified propeller and the zero-thrust propeller under the corresponding rotational speed value of each of the modified propeller and the zero-thrust propeller and a power difference value between the criterial propeller and the zero-thrust propeller under the corresponding rotational speed value of each of the criterial propeller and the zero-thrust propeller, are obtained, respectively; an aerodynamic coefficient K·cotθ_{w} of the modified propeller and an aerodynamic coefficient K·cotθ_{w} of the criterial propeller are obtained according to the engineering formulae (8) and are compared and analyzed;

in the aspect of simulation, a three-dimensional model of the criterial propeller and a three-dimensional model of the modified propeller are obtained, and thrust values and torque values of the criterial propeller and the modified propeller at several corresponding rotational speed values are set and recorded to obtain data arrays for the criterial propeller and the modified propeller; an aerodynamic coefficient K·cotθ_{w} of the modified propeller and an aerodynamic coefficient K·cotθ_{w} of the criterial propeller are obtained according to the calculation formulae (9) and are compared and analyzed.

In some embodiments, for the criterial blade with known design parameters, the zero-thrust propeller is manufactured by a following method, including:

taking the criterial blade, establishing a cylindrical coordinate system with an intersection between an axis of a rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; where the positive direction of a polar angle is a rotation direction of the common propeller, and in a normal direction of the rotational plane, the positive direction of the z-axis is a direction that points from the pressure surface of the criterial blade to a suction surface of the criterial blade; any point on a profile of the criterial blade is expressed as (r, ψ, z) in cylindrical coordinates, where r, ψ, z represent a polar radius, the polar angle and a z-coordinate, respectively; and

performing an overall coordinate transformation on all profile points directly into new profile points to obtain a blade contour of the zero-thrust propeller according to following rules: converting

$$( r , ψ , z ) into ( r , ( ψ - {ψ}_{0} ) cos θ + \frac{z - {z}_{0}}{r} sin θ + {ψ}_{0} , ( z - {z}_{0} ) cos θ - r ( ψ - {ψ}_{0} ) sin θ + {z}_{0} ) .$$

In some embodiments, for the criterial blade with unknown design parameters, a zero-thrust propeller is manufactured by a following method, including:

taking the criterial blade, establishing a cylindrical coordinate system with an intersection between an axis of a rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; where a positive direction of the polar angle is a rotation direction of the common propeller, and in a normal direction of the rotational plane, a positive direction of the z-axis is a direction that points from the pressure surface of the criterial blade to a suction surface of the criterial blade; and

taking chordwise sections at all characteristic positions and several ordinary positions on the criterial blade which represent an overall contour of the criterial blade, and selecting points at all characteristic positions and several ordinary positions on each of the chordwise sections which represent an overall contour of each of the chordwise sections, and expressing the points as (r, ψ, z) in cylindrical coordinates; where r, ψ, z represent a polar radius, the polar angle and a z-coordinate, respectively;

calculating a value of the angle of attack θ of the blade element corresponding to each of the chordwise sections by using the cylindrical coordinates of points where a chord is tangent to a leading edge contour and a trailing edge contour;

determining a rectangular coordinate of a tilting base point O of each of the chordwise sections as (rψ₀, z₀) and the cylindrical coordinate of the tilting base point O of each of the chordwise sections as (r, ψ₀, z₀);

tilting each of the chordwise sections around a corresponding tilting base point O to make the angle of attack of a corresponding blade element zero;

performing a coordinate transformation on all profile points to obtain coordinates of new profile points according to following rules: converting (r, ψ, z) into

$$( r , ( ψ - {ψ}_{0} ) cos θ + \frac{z - {z}_{0}}{r} sin θ + {ψ}_{0} , ( z - {z}_{0} ) cos θ - r ( ψ - {ψ}_{0} ) sin θ + {z}_{0} ) ;$$

smoothly connecting all the new profile points with a same polar radius into new chordwise sections; and

smoothly connecting all the new chordwise sections into a complete blade whose rotational radius is R to obtain a blade profile of the zero-thrust propeller.

Compared with the prior art, the embodiments have the following technical effects.

The design method for the blade with the orientation structures in the embodiments is universal to blades with various structures, and is independent of whether the blade parameters are known or not.

The performance of the propeller or the fan having the modified blades with the orientation structures designed based on the design method can be obviously improved. To sum up, the orientation grooves on the suction side of each blade delay and weaken airflow separation at the low-pressure zone nearby each groove, and help guiding airflow toward the orientation awls to be induced as discrete and thready streamwise vortices which would straightly shedding off backwards at the awl tips, this effect results in the drag reduction and noise sonification weakening to blades rotating, and further narrows and weakens the low-pressure region above the blade back, ulteriorly, the downwash swirling from the pressure side to the suction side at the trailing edge, as well as the subsequent turbulent vortices are greatly suppressed. As a result, the static pressure difference between the pressure and suction sides of the blade is increased, which further increases the thrust. In the aspect of practical verification, the aerodynamic coefficient K·cotθ_{w} of the modified propeller is significantly increased than the aerodynamic coefficient K·cotθ_{w} of the criterial propeller.

### BRIEF DESCRIPTION OF THE DRAWINGS

In order to explain the embodiments of the present disclosure or the technical schemes in the prior art more clearly, the drawings that need to be used in the embodiments will be briefly introduced. Obviously, the drawings in the following description are only some embodiments of the present disclosure. For those skilled in the art, other drawings can be obtained according to these drawings without creative labor.

FIG. 1 is a schematic diagram of making chordwise sections on a criterial blade from an axial perspective.

FIG. 2 is a schematic diagram of the chordwise sections of selecting several profile points.

FIG. 3 is a schematic diagram of making m+l awl-groove benchmark surfaces from the axial perspective.

FIG. 4 is a schematic diagram of each awl-groove benchmark surface after unidirectional or bidirectional rotation of an angle γ from the axial perspective.

FIG. 5 is a schematic structure diagram of a blade after orientation awls are obtained by cutting materials.

FIG. 6 is a schematic diagram of blunting arcs in the process of blunting for connecting angles of the orientation awls.

FIG. 7 is a schematic diagram of an enlarged structure of the blunting arc in FIG. 6.

FIG. 8 is a schematic diagram of the cylindrical coordinates for a propeller.

FIG. 9 is a schematic diagram of the orientation structures.

FIG. 10 is a schematic diagram of a chordwise section where the bottom curve of the orientation groove is located.

FIG. 11 is a schematic diagram of the orientation structures in the chordwise perspective.

FIG. 12 is a schematic diagram of the combination of the orientation awls and the orientation grooves.

FIG. 13 is a schematic diagram of the modified propeller.

FIG. 14 is a schematic diagram of a test method.

### LIST OF THE REFERENCE CHARACTERS

1 criterial blade; 2 rotational shaft; 3 chordwise section; 4 thickness direction; 5 chord direction; 6 thickness line; 7 chord line; 8 first awl-groove benchmark surface; 9 (m+1)-th awl-groove benchmark surface; 10 orientation awl; 11 awl tip; 12 orientation groove; 13 groove bottom curve of the (m−1)-th orientation groove; 14 action line for pure aerodynamic impact on the pressure surface of the blade element; and 15 modified propeller.

### DETAILED DESCRIPTION OF THE EMBODIMENTS

The technical schemes in the embodiments of the present disclosure will be clearly and completely described with reference to the drawings in the embodiments of the present disclosure hereinafter. Obviously, the described embodiments are only some embodiments of the present disclosure, rather than all of the embodiments. Based on the embodiment of the present disclosure, all other embodiments obtained by those skilled in the art without creative labor fall within the scope of protection of the present disclosure.

The embodiments aim to provide a design method for a blade with orientation structures, a blade and a performance test method for a blade, so as to solve the problems existing in the prior art. The design method is universal to blades with various structures, and the performance of a propeller or a fan with modified blades with orientation structures designed based on the method can be obviously improved.

In order to make the above objects, features and advantages of the embodiments more obvious and understandable, the present disclosure will be explained in further detail with reference to the drawings and detailed description of the embodiments hereinafter.

### Embodiment 1

This embodiment provides a design method for a blade with orientation structures. The blades mentioned in the embodiment include fan blades and propeller blades. The pitch of the fan is usually fixed. The propeller blades can be classified into fixed-pitch propeller blades and variable-pitch propeller blades. The orientation structures of the fixed-pitch propeller blade include orientation awls 10 and orientation grooves 12, while the orientation structures of the variable-pitch propeller blade only include orientation awls 10. Therefore, two different types of propeller blades are described separately.

### (I) Modification Design for the Fan Blade and the Fixed-Pitch Propeller Blade

Both the fan and the fixed-pitch propeller are rotors with a constant angle of attack of blade, and their modification methods are completely identical. A type of fixed-pitch propellers can be selected as a criterial propeller and a blade of the selected fixed-pitch propeller as a criterial blade 1. An area A_{c} of a pressure surface of the criterial blade, a rotational radius R of the fixed-pitch propeller (that is, a rotational radius of the criterial blade) and a length of a characteristic chord c_{f} of the criterial blade are measured and recorded, where c_{f} is usually taken as an airfoil chord length at the radial position of 2/3R on the criterial blade.

In Step 1, a primary treatment is performed.

According to different sources of criterial blades, the primary treatment is divided into two schemes. The criterial blade in Scheme 1 is designed independently, that is, the design parameters are known. The criterial blade in Scheme 2 is designed non-independently, that is, the design parameters are unknown.

In the Scheme 1, Step 2 is executed directly without performing the primary treatment on the criterial blade 1.

In the Scheme 2, performing the primary treatment on the criterial blade 1 is to supply size surplus in a chord direction 5 and a thickness direction 4 of the blade for the succeeding manufacturing of orientation awls 10 and orientation grooves 12, while the aerodynamic characteristics of the criterial propeller blade is able to be remained, which can be realized by a following method. The following method is also a universal method to stretch or shrink the criterial blade 1 at any multiple in an airfoil chord direction and an airfoil thickness direction. The airfoil chord direction and the airfoil thickness direction are specified as follows. FIG. 2 shows chordwise sections 3 of the criterial blade 1, and a line segment AB is a chord line 7. A straight line parallel to the chord line AB and tangent to the suction side of the chordwise section 3 is drawn, the tangent point is denoted as point C, a straight line OC is intersected with the chord line AB perpendicularly at point O, and the straight line OC is referred to as a thickness line 6 of the criterial blade 1; a direction of a ray OA is the chord direction 5 of the criterial blade 1, the direction of the ray OC is the thickness direction 4 of the criterial blade 1, and the thickness direction 4 is a normal direction of the chord direction 5.

(1) The criterial blade 1 is scanned, and a contour of the scanned criterial blade 1 is input into computer software. A cylindrical coordinate system is established with an intersection between an axis (i.e., the z-axis) of a rotational shaft 2 of the criterial blade 1 and a rotational plane of the criterial blade 1 as a pole O, a ray passing through the pole O on the rotational plane as a polar axis Ox, and the axis of the rotational shaft 2 of the criterial blade 1 that perpendicular to the rotational plane as a z-axis. A positive direction of a polar angle is the rotation direction of the propeller, and in a normal direction of the rotational plane, a positive direction of the z-axis is a direction that points from the pressure surface of the criterial blade 1 to a suction surface of the criterial blade 1.

(2) The chordwise sections 3 at all characteristic positions and several ordinary positions on the criterial blade 1 which can represent an overall contour of the criterial blade 1 are taken. The characteristic positions include positions where curvatures of the criterial blade 1 change obviously and positions where boundary value sizes of the criterial blade 1 are located, that is, the positions where shape of the criterial blade 1 changes. The ordinary positions include positions where curvatures of the criterial blade 1 are unchanged or changed by a small amplitude, and positions where general sizes of the criterial blade 1 are located. Selection principle for the characteristic positions and the ordinary positions requires them to represent the overall contour of the criterial blade 1, that is, the overall contour of the criterial blade 1 can be obtained through the smooth connection of a contour of each chordwise section 3 after contours of the chordwise sections 3 of the characteristic positions and the ordinary positions are available.

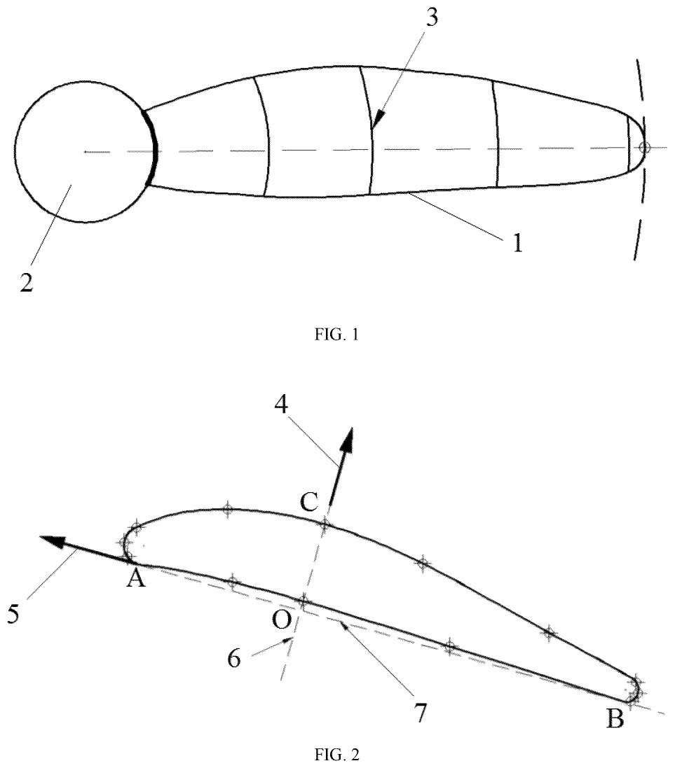

In an example by FIG. 1, six chordwise sections 3 are drawn, and an arc denotes a chordwise section 3 from the axial perspective. Profile points at all characteristic positions and several ordinary positions on each chordwise section 3 which represent the overall contour of the chordwise section 3 are selected. Selection of the profile points at the characteristic positions and the ordinary positions is in a similar way to the selection of the chordwise sections 3 mentioned above in terms of principle, which is required to represent an overall shape of the chordwise section 3. The profile points at the ordinary positions can be selected according to the actual shape of criterial blade 1. In an example by FIG. 2, thirteen profile points of a certain chordwise section 3 are marked from a radial perspective. Coordinates of all profile points in the cylindrical coordinate system are marked. Generally, the coordinate of a certain profile point can be denoted as (r, ψ, z), where r, ψ, z represent a polar radius, the polar angle and a z-coordinate, respectively. It should be noted that the coordinates of the profile points can be automatically generated in the software, but other parameters of the chordwise section 3 remain unknown.

(3) The value of an angle of attack θ of a blade element and the coordinate (r, ψ₀, z₀) of a tilt base point O of each chordwise section 3 are calculated by the cylindrical coordinates of the points where a chord on the corresponding chordwise section 3 is tangent to a leading edge contour and a trailing edge contour (that is, point A and point B in FIG. 2).

(4) In order to ensure the performance of the modified blade with the orientation structures, it is required that an area Aₘ of the pressure surface of the modified blade is equal to the area A_{c} of the pressure surface of the criterial blade 1. Therefore, it is necessary to stretch the criterial blade 1 in the chord direction 5 before the orientation grooves 12 are formed by cutting. Moreover, before the orientation grooves 12 are formed by cutting, stretching the criterial blade 1 in the thickness direction 4 is able to supply size surplus in thickness for cutting the orientation grooves 12 to ensure the strength of the blade. However, for the criterial blade 1 with unknown design parameters, a stretching coefficient t₁ in the chord direction 5 and a stretching coefficient t₂ in the thickness direction 4 are both unknown. According to experience, appropriate values of t₁ and t₂ can be given first (the reason why the appropriate values can be given will be explained in the following steps). t₁ of the criterial blade 1 is preliminarily determined by a matching relationship between the length of the subsequently formed orientation awl 10 and the chord length. A ratio of the length of the orientation awl 10 to the chord length is larger for the blade with a higher rotational speed. t₂ of the criterial blade 1 is determined by the depth d of the orientation groove 12 in the subsequent steps and the strength requirement of the blade. Generally, t₁>t₂>1, such that a profile of the stretched blade appears flatter than a profile of the criterial blade 1.

It should be noted that the stretching for the criterial blade 1 in the chord direction 5 and the thickness direction 4 herein is mainly for the self-consistency in logic and rationality in design. t₁ needs to be finally determined by calculation in the following steps to strictly satisfy Aₘ=A_{c}. After t₁ is finally calculated, the stretching operation for the criterial blade 1 will be performed again to supply accurate chordwise size surplus (that is, area surplus) for formation of the orientation awls 10 by cutting.

(5) The chordwise section 3 of the criterial blade 1 is stretched according to the given t₁ and t₂, and the profile point coordinate (r, ψ, z) is converted into

$$( r , ( ψ - {ψ}_{0} ) ( {t}_{1} {cos}^{2} θ + {t}_{2} {sin}^{2} θ ) + \frac{z - {z}_{0}}{r} ( {t}_{1} - {t}_{2} ) sin θ cos θ + {ψ}_{0} , r ( ψ - {ψ}_{0} ) sin θ cos θ ( {t}_{1} - {t}_{2} ) + ( z - {z}_{0} ) ( {t}_{1} {sin}^{2} θ + {t}_{2} {cos}^{2} θ ) + {z}_{0} ) ,$$

in which the profile points with the same polar radius must correspond to the same angle of attack of the blade element and the same tilt base point, and they will not change before and after the conversion. All new profile points with the same polar radius are smoothly connected to form a new chordwise section 3 to replace an original chordwise section 3. Then all new chordwise sections 3 are smoothly connected into a complete blade whose rotational radius is R, so as to form the stretched blade. An area of the pressure surface of the stretched blade is Aₘ_{₀}=t₁A_{c}.

In Step 2, the orientation awls 10 and the orientation grooves 12 are positioned.

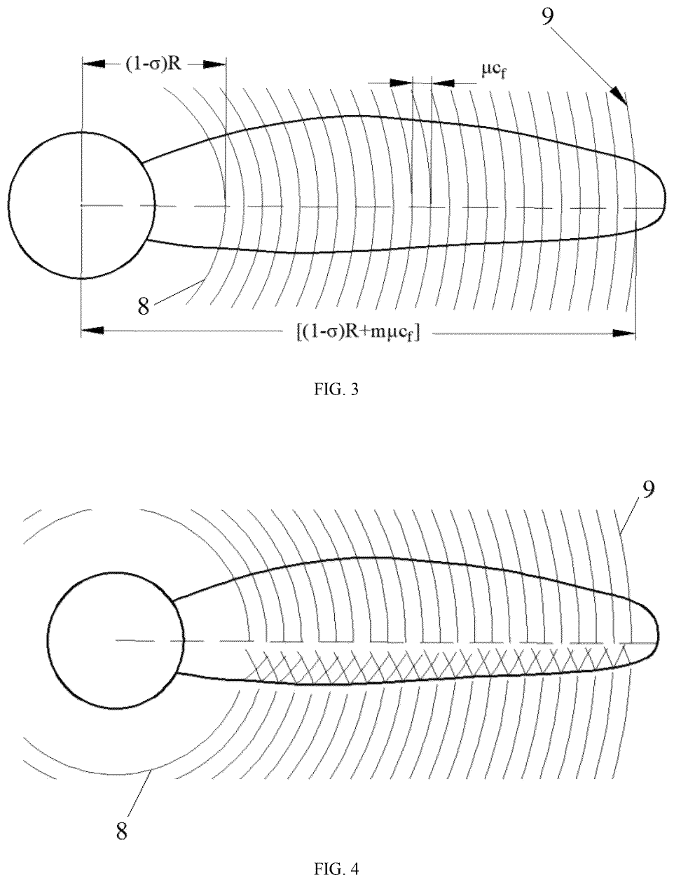

As shown in FIG. 3, from the axial perspective, (m+1) equidistant cylindrical sides are created with the rotational shaft 2 of the criterial blade 1 or the stretched blade as an axis (it should be understood that the criterial blade 1 is a design object for Scheme 1 and the stretched blade is a design object for Scheme 2). Radius values of these cylindrical sides form an arithmetic progression with a first term of (1−σ) R and a tolerance of μc_{f}, where m is an integer in the range

$$( \frac{σ R}{μ {c}_{f}} - 2 , \frac{σ R}{μ {c}_{f}} - 1 ] ;$$

these (m+1) cylindrical sides are referred to as the awl-groove benchmark surfaces. In an example by FIG. 3, σ is ¾, μ is 1/7,

$$\frac{R}{{c}_{f}}$$

is about 4.40, and m is 22. It should be pointed out that σ and μ are ought to be determined by performance requirements and based on the comprehensive consideration of design routines, experiences and aerodynamic laws.

$$\frac{R}{{c}_{f}}$$

relates to the condition of the rotational speed of the propeller, and the matching relationship between the lengths of the orientation awls 10 and the chord length is reflected by μ.

In Step 3, the contour of the orientation awls 10 are determined.

From the axial perspective, after Step 2, the positions where intersections between the awl-groove benchmark surfaces and the trailing edge of the criterial blade 1 or the trailing edge of the stretched blade are located are positions where awl tips 11 of the orientation awls 10 are located. Two semi-awls are respectively formed at a radial position where the first awl-groove benchmark surface 8 that is the innermost awl-groove benchmark surface is located and a radial position where the (m+1)-th awl-groove benchmark surface 9 that is the outermost awl-groove benchmark surface is located, and (m−1) complete orientation awls 10 are formed in the middle between both of the semi-awls. Specifically, around an axial line passing through the awl tip 11, each awl-groove benchmark surface between the first awl-groove benchmark surface 8 and the (m+1)-th awl-groove benchmark surface 9 is rotated at an angle of γ-degree toward the blade tip and is rotated at the angle of γ-degree toward the blade root to form two circular arc surfaces, while the innermost awl-groove benchmark surface is rotated at the angle of γ-degree toward the blade tip to form an circular arc surface, and the outermost awl-groove benchmark surface is rotated at the angle of γ-degree toward the blade root to form an circular arc surface. These arc surfaces are side surfaces of the orientation awls 10, and an awl angle formed by the two side surfaces of each orientation awl 10 is 2γ except for the innermost semi-awl and the outermost semi-awl. Meanwhile, the orientation awls 10 should be gradually more obvious from the blade root to the blade tip, which should be embodied in the fact that awl tip angles gradually decrease over this trend. Rotation angle γ can be determined by the conventional design manuals, the experiences and the aerodynamic laws. Specifically, the change rule for γ values is that, these γ values from the blade root to the blade tip form an arithmetic progression with a first term of γ₀ and a tolerance of

$$\frac{{γ}_{m} - {γ}_{0}}{m} .$$

For the criterial blade 1 with known design parameters, the γ value should be slightly larger than a design value to reserve angle surplus for the reduction of the angle of the awl tip 11 resulted from the succeeding chordwise stretching. For the criterial blade 1 with unknown design parameters, the γ value should be equal to the design value. It should be pointed out that due to the existence of the angle of attack of blade element, a true awl angle of each orientation awl 10 is slightly less than 2γ to varying degrees. FIG. 4 is an example of operation from the axial perspective. In the example, γ₀ is

$$\frac{3 π}{15} ,$$

and γₘ is

$$\frac{2 π}{15} .$$

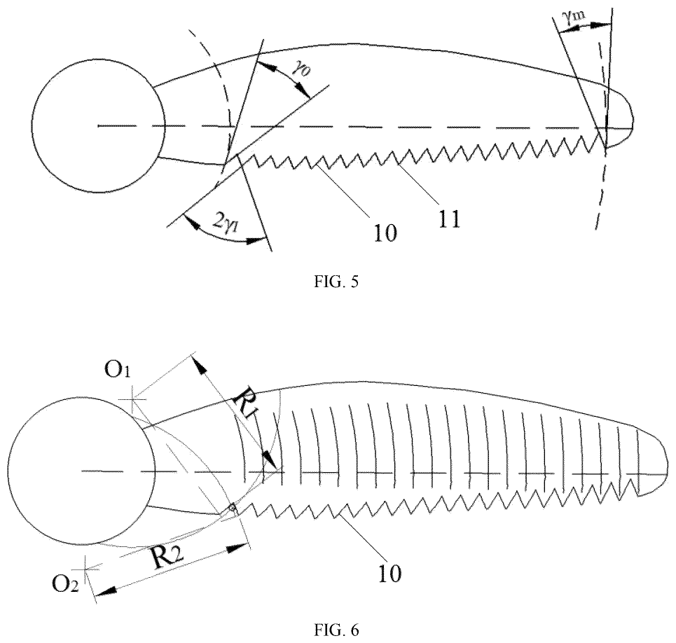

The series of orientation awls 10 is a new trailing edge of the criterial blade 1, as shown in FIG. 5.

In Step 4, the connecting angles of the orientation awls 10 are blunted.

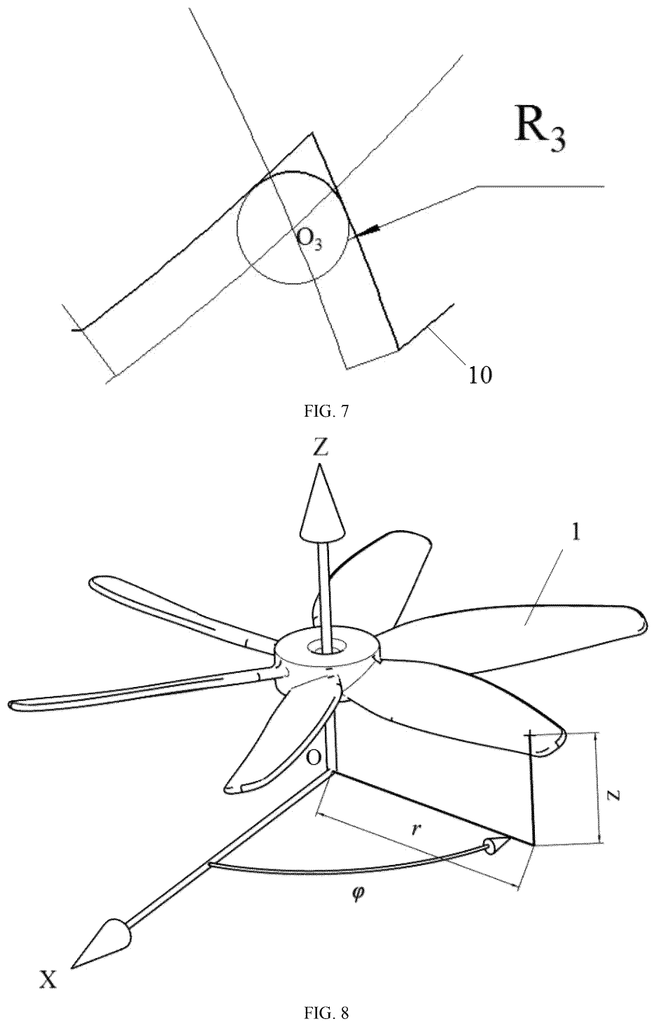

A connecting angle through which every two adjacent orientation awls 10 are connected need to be blunted. The blade with the orientation awls 10 needs to be blunted for m times. There are a series of cylindrical sides are taken for blunting. A blunting process of one of the connecting angles is illustrated as an example, and description below is made in a two-dimensional context due to the corresponding operations are performed from the axial perspective. A radius R₃ of a blunting arc is selected, and R₃ can be determined by calculations and experiences. The blunting arc is located inside the connecting angle and is tangent to both sides of the connecting angle. It should be pointed out that R₃ should be gradually increased from the blade root to the blade tip, such that a blunted portion is gradually enlarged from the blade root to the blade tip. It is assumed that a center of an arc where an inner side (the side adjacent to the rotational shaft 2) of the connecting angle locates is O₁ with a radius of R₁. A center of an arc where an outer side (the side away from the rotational shaft 2) of the connecting angle locates is O₂ with a radius of R₂. A first circle is drawn with O₁ as the center and (R₁+R₃) as a radius, and a second circle is drawn with O₂ as the center and (R₂−R₃) as a radius, in which the first circle and the second circle intersect at point O₃. A third circle is drawn with O₃ as a center and R₃ as the radius to obtain a required blunting arc, as shown in FIG. 6 and FIG. 7. Tangent points on the blunting arc and both sides of the connecting angle are found. Both sides of the connecting angle and an arc between the two tangent points enclose a cavity, and this cavity is filled with solids to complete the forming and manufacturing of blunting of the connecting angle. It should be noted that in an actual manufacturing process, it is also available to replace an edge line at a tip of the connecting angle with a blunting arc, that is, connecting the blunting arc and both sides of the connecting angle to form a new contour of orientation awl 10, and then cutting along the new contour of orientation awls 10. The blunting of the remaining connecting angles operates similar to the above steps.

In Step 5, an area of the pressure surface of the blade with the orientation awls 10 is accurately determined.

Scheme 1: For the Criterial Blade 1 with Known Design Parameters

The blade with the orientation awls 10 is stretched in the chord direction 5 and the thickness direction 4 to ensure an area of pressure surface of the stretched modified blade equal to an area of pressure surface of the criterial blade 1 to supply size surplus in the thickness direction 4 of the blade for the succeeding manufacturing of the orientation grooves 12, meanwhile the aerodynamic characteristics of the criterial blades 1 of the criterial propeller are able to be remained, which can be realized by the following ways.

(1) The area Aₘ_{₁} of the pressure surface of the blade with the orientation awls 10 is measured and recorded.

(2) The cylindrical coordinate system is established with the intersection between the axis of the rotational shaft 2 of the criterial blade 1 and the rotational plane of the criterial blade 1 as the pole O, the ray passing through the pole O on the rotational plane as the polar axis Ox, and the axis of the rotational shaft 2 of the criterial blade 1 that perpendicular to the rotational plane as the z-axis. The positive direction of the polar angle is the rotation direction of the propeller, and in the normal direction of the rotational plane, the positive direction of the z-axis is a direction that points from the pressure surface of the criterial blade 1 to the suction surface of the criterial blade 1. Any point on the surface profile of the criterial blade 1 with the orientation awls 10 is expressed as (r, ψ, z) in cylindrical coordinates, where r, ψ, z represent the polar radius, the polar angle and the z-coordinate, respectively.

(3) An overall coordinate transformation is performed on all profile points directly into new profile points by programming according to the following rules: (r, ψ, z) is converted into

$$( r , ( ψ - {ψ}_{0} ) ( {t}_{1} {cos}^{2} θ + {t}_{2} {sin}^{2} θ ) + \frac{z - {z}_{0}}{r} ( {t}_{1} - {t}_{2} ) sin θ cos θ + {ψ}_{0} , \\ r ( ψ - {ψ}_{0} ) sin θ cos θ ( {t}_{1} - {t}_{2} ) + ( z - {z}_{0} ) ( {t}_{1} {sin}^{2} θ + {t}_{2} {cos}^{2} θ ) + {z}_{0} ) ,$$

by which a geometric significance is reflected, that is, a stretching in the both the overall chord direction and the overall thickness direction 4 to a blade of the propeller is achieved by stretching each blade element at a multiple of t₁ in its chord direction 5 and a multiple of t₂ in its thickness direction 4 to obtain the modified blade, in which the angle of attack θ of the blade element and the tilt base point O of the chordwise section 3 where the profile points are located are both known in the conversion formula. θ is the angle of attack of the blade element of the chordwise section 3 where the profile points are located, and the tilt base point O (r, ψ₀, z₀) is the tilt base point of the chordwise section 3 where the profile points are located. θ depends on the radial twisting law of the blade and the radial positions of the profile points, which is a function of r. A position of the tilt base point O depends on the chord of the criterial blade 1 and the shape of the curve contour on the suction side of the criterial blade 1, and the tilt base point can be located by the curve equations of the contour of the criterial blade 1. Both of the value of θ and the position of point O will not change before and after the conversion. In the conversion formula, the chordwise stretching coefficient of the criterial blade 1 is

$${t}_{1} = \frac{{A}_{c}}{{A}_{{m}_{1}}} ,$$

A_{c} is an area of the pressure surface of the criterial blade 1, t₂ is an stretching coefficient of the criterial blade 1 in the thickness direction 4, and t₁>t₂>1, such that a new airfoil contour appears flatter than an original airfoil contour. A blade enclosed by the new profile points is the modified blade which is stretched at a multiple of t₁ in its chord direction 5 and a multiple of t₂ in its thickness direction 4 on the basis of the blade with the orientation awls 10. The above coordinate conversion satisfies Aₘ_{₂}=t₁Aₘ_{₁}=A_{c}, where Aₘ_{₂} is an area of a pressure surface of the single modified blade.
Scheme 2: For the Criterial Blade 1 with Unknown Design Parameters

t₁ in Step 1 is finally determined by calculation in this step to strictly satisfy Aₘ=A_{c}. The specific calculation method including: measuring and recording the difference of the area of the pressure surface of the blade before and after forming the blunted orientation awls 10 by cutting, which is an area of the pressure surface of the cut material of the blade after performing the primary treatment, and is denoted as A_{cut}. Because the interval μc_{f} between the adjacent orientation awls 10, the angle of each of the orientation awls 10 and the radius of each of the blunting arcs are all determined design parameters and will not be changed, the area of the pressure surface A_{cut} of the cut material is a constant value. It is assumed that A_{c}=Aₘ=Aₘ_{₀}−A_{cut}, and

$${t}_{1} = 1 + \frac{{A}_{c u t}}{{A}_{c}}$$

is obtained. At this point, t₁ is finally determined. The operations from Step 2 to Step 4 are re-executed to obtain the modified blade with the orientation awls 10, where the area of the pressure surface of the modified blade is completely equal to the area of the pressure surface of the criterial propeller blade. That is, when Step 2 is executed, the criterial blade 1 is directly stretched by the chordwise stretching coefficient

$${t}_{1} = 1 + \frac{{A}_{c u t}}{{A}_{c}} ,$$

and then the initial contour surface of the blunted orientation awls 10 is obtained by cutting the material of the stretched blade. Finally, the orientation awls 10 are obtained at the trailing edge of the stretched blade. It should be pointed out that A_{cut} is a constant value that does not change with t₁ because the design parameters that the orientation awls 10 involved remain unchanged. In addition, the precision of t₁ depends on the number of chordwise sections 3, and there should not be too few chordwise sections 3 at the ordinary positions.

After Step 5, it is not difficult to see that for the criterial blade 1 with known design parameters, the initial contour of the orientation awls 10 is obtained first by cutting the material of the criterial blade 1, then the final contour of the orientation awls 10 is obtained by blunting the awl tips 11, and finally, the modified blade is obtained by stretching in the chord direction 5 and the thickness direction 4, such that the area of the pressure surface of the modified blade is equal to the area of the pressure surface of the criterial blade 1. For the criterial blade 1 with unknown design parameters, an accurate chord stretching coefficient is firstly calculated, and after the criterial blade 1 are stretched in the chord direction 5 (base on the accurate chord stretching coefficient) and the thickness direction 4, the initial contour of the orientation awls 10 is obtained by cutting the material of the stretched criterial blade 1, then the final contour of the orientation awls 10 is obtained by blunting the awl tips 11, so as to obtain the modified blade, such that the area of the pressure surface of the modified blade is equal to the area of the pressure surface of the criterial blade 1.

In Step 6, the orientation grooves 12 are formed on a back of the modified blade.

### (1) Positions of the Orientation Grooves 12 and Sizes of the Orientation Grooves 12 in the Chord Direction 5 and the Thickness Direction 4

Operations are carried out from the axial perspective. The awl-groove benchmark surfaces in Step 2 are also benchmarks for forming the orientation grooves 12 on the back of the modified blade, so as to realize functional cooperation between the orientation grooves 12 and the orientation awls 10. One of the orientation grooves 12 is taken as an example hereinafter to introduce its forming and manufacturing method. The awl-groove benchmark surface intersects the pressure surface of the blade at a curve segment AB on a pressure side of a corresponding chordwise section 3. A straight line OC intersects the curve segment AB at point E, and a length of a line segment CE is a thickness δ of the blade. A point D on the line segment CE is taken to make a length of the line segment CD as a constant groove depth d, which always satisfies d=λ·δₘ₋₁, where δₘ₋₁ represents the thickness of the blade on the chordwise section 3 where the groove bottom curve 13 of the (m−1)-th orientation groove is located. It is suggested that λ should be taken a value of about 0.2. A curved segment A′B′ crossing the point D is parallel to the curved segment AB, and intersects the airfoil contour at a point A′ and a point B′. The curved segment A′B′ is the groove bottom curve of the orientation groove 12, as shown in FIG. 10 and FIG. 12.

### (2) the Shapes and Radial Dimensions of the Orientation Grooves 12

From the chordwise perspective, the groove type of all the orientation grooves 12 is a circular-arc groove with the same depth d as that of the (m−1)-th orientation groove, that is, the shape of each of the orientation grooves 12 on the radial section of the blade appear as a circular-arc, where a section perpendicular to the blade surface along a dotted line in FIG. 12 is one of the radial sections of the blade. An intersection line between a wall surface of the same one orientation groove 12 and any plane passing through the axis of the rotational shaft 2 is a circular arc with the same curvature. The bottom of the circular-arc groove is the curved segment A′B′. The same one orientation groove 12 has a same arc radius p. Arc radii ranging from ρ₁ to ρₘ of the m orientation grooves 12 gradually increase from the blade root to the blade tip to form an arithmetic progression with a first term of ρ₁ and a tolerance

$$\frac{{ρ}_{m} - {ρ}_{1}}{m - 1} , where d < {ρ}_{1} < {ρ}_{m} < \frac{{μ}^{2} {c}_{f}^{2}}{8 d} + \frac{d}{2} ,$$

such that any adjacent orientation grooves 12 do not intersect with each other. After this step, the m orientation grooves 12 with an identical depth but increasing widths from the blade root to the blade tip are formed on the blade.

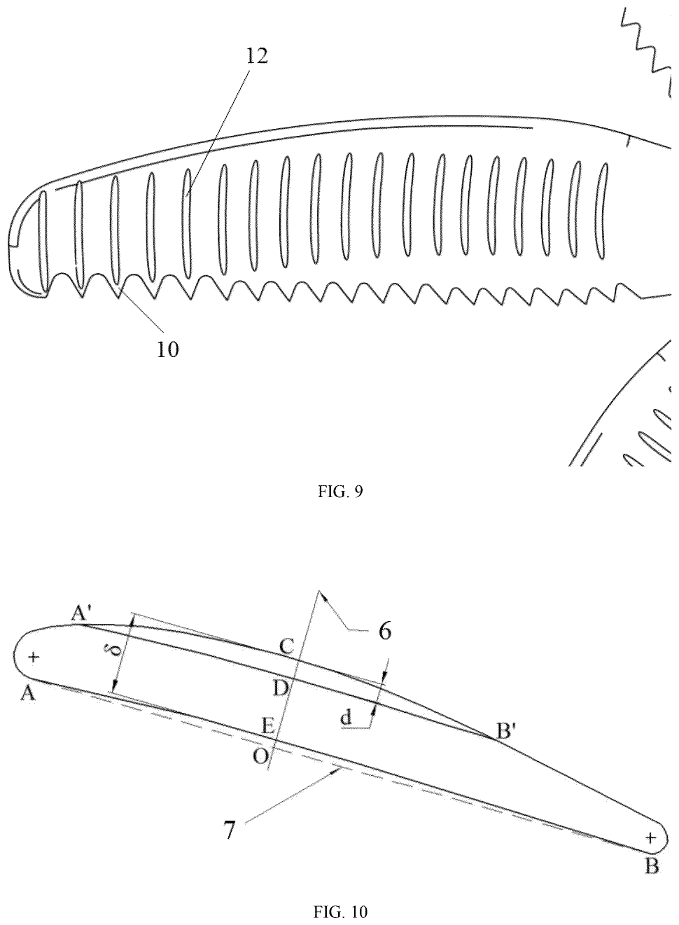

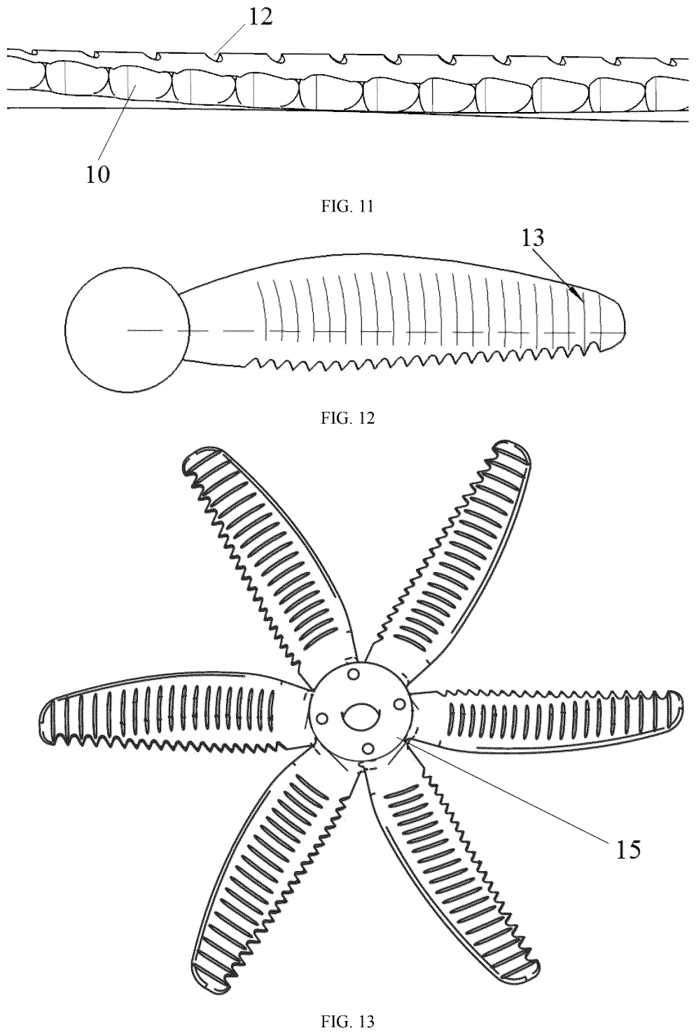

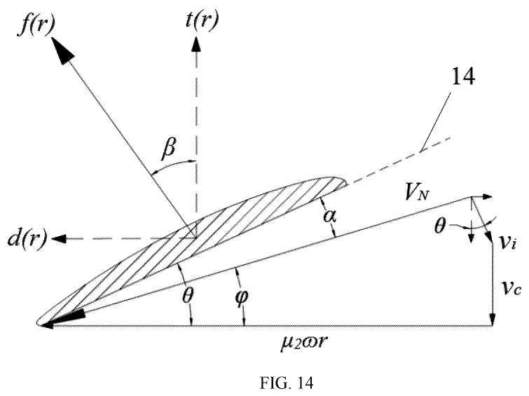

At this point, the orientation structures on the blade are finished, as shown in FIG. 9, the other blades on the propeller are obtained by rotationally duplication, and the modified blades with the orientation structures are finished.

### (II) A Modification Design for the Variable-Pitch Propeller Blade

The orientation structures of the variable-pitch propeller blades only include the orientation awls 10. A variable-pitch propeller is directly selected as the criterial propeller. An area of a pressure surface A_{c} of a single criterial blade 1, a rotational radius R of the criterial blade 1 and the characteristic chord length c_{f} of the criterial blade 1 are measured and recorded when the criterial propeller is under an arbitrary pitch; where c_{f} is usually taken as an airfoil chord length at a radial position of 2/3R on the propeller blade.

In Step 1, a primary treatment is performed.

According to the different sources of criterial blades 1, the primary treatment is divided into two schemes. The criterial blade 1 in Scheme 1 is designed independently, that is, design parameters are known. The criterial blade 1 in Scheme 2 is designed non-independently, that is, design parameters are unknown.

In the Scheme 1, Step 2 is executed directly without the primary treatment to the criterial blade 1.

In the Scheme 2, performing the primary treatment to the criterial blade 1 is to supply size surplus in a chord direction 5 of the blade for the succeeding manufacturing of the orientation awls 10, meanwhile the aerodynamic characteristics of the criterial propeller blade are able to be remained, which can be realized by the following method. The following method is also a universal method to stretch or shrink the criterial blade 1 at any multiple in an airfoil chord direction. The airfoil chord direction and the airfoil thickness direction 4 of the criterial blade 1 are specified in the same way as that in the primary treatment to the criterial blade 1 of the fixed-pitch propeller with unknown design parameters.

(1) The criterial blade 1 is scanned, and the contour of the scanned criterial blade 1 is input into computer software. A cylindrical coordinate system is established with an intersection between an axis of a rotational shaft 2 of the criterial blade 1 and a rotational plane of the criterial blade 1 as a pole O, a ray passing through the pole O on the rotational plane as a polar axis Ox, and the axis of the rotational shaft 2 of the criterial blade 1 that perpendicular to the rotational plane as a z-axis; a positive direction of a polar angle is a rotation direction of the propeller, and in a normal direction of the rotational plane, a positive direction of the z-axis is a direction that points from a pressure surface of the criterial blade 1 to a suction surface of the criterial blade 1.

(2) The chordwise sections 3 at all characteristic positions and several ordinary positions of the criterial blade 1 are taken. Profile points of all characteristic positions and several ordinary positions are selected on each chordwise section 3. Coordinates of all profile points in the cylindrical coordinate system are marked. Generally, the coordinate of a certain profile point can be denoted as (r, ψ, z), where r, ψ, z represent a polar radius, the polar angle and the z-coordinate, respectively.

(3) The value of an angle of attack θ of the blade element and the coordinate (r, ψ₀, z₀) of a tilt base point O of each chordwise section 3 are calculated by the cylindrical coordinates of the points where a chord on the corresponding chordwise section 3 is tangent to the leading edge contour and the trailing edge contour (that is, the point A and the point B in FIG. 2).

(4) According to the length of the orientation awls 10, the chord stretching coefficient t₁ of the criterial blade 1 is preliminarily determined, such that Aₘ=A_{c} is roughly satisfied by the criterial blade 1 after which is turned into a modified blade with the orientation awls 10 by stretching in the chord direction 5 at a multiple of t₁ and cutting, where Aₘ is the area of the pressure surface of the modified blade, and A_{c} is the area of the pressure surface of the criterial blade 1. t₁ is preliminarily determined by the matching relationship between the chord length and the lengths of the orientation awls 10 that formed subsequently, and a ratio of the length of the orientation awls 10 to the chord length is larger for the blade with a higher rotational speed. t₁ needs to be finally determined by calculation in Step 3 to strictly satisfy Aₘ=A_{c}.

(5) Each chordwise section 3 needs to be stretched. Specifically, the coordinates (r, ψ, z) of all the profile points are converted into

$$( r , ( ψ - {ψ}_{0} ) ( {t}_{1} {cos}^{2} θ + {sin}^{2} θ ) + \frac{z - {z}_{0}}{r} ( {t}_{1} - 1 ) sin θcosθ + {ψ}_{0} , r ( ψ - {ψ}_{0} ) sin θ cos θ ( {t}_{1} - 1 ) + ( z - {z}_{0} ) ( {t}_{1} {sin}^{2} θ + {cos}^{2} θ ) + {z}_{0} ) ,$$

in which the profile points with the same polar radius must correspond to the same angle of attack of the blade element and the tilt base point, and they will not change before and after the conversion. All new profile points with the same polar radius are smoothly connected to form a new chordwise section to replace an original chordwise section 3. Then all new chordwise sections are smoothly connected into a complete blade whose rotational radius is R, so as to form a primarily treated criterial blade contour. The area of the pressure surface of the stretched blade is Aₘ_{₀}=t₁A_{c}.

In Step 2, the orientation awls 10 are manufactured.

The pitch of the modified blade of the modified propeller 15 after Step 1 is set as lᵥ in the cruising state, and the operations from Step 2 to Step 4 in the above-mentioned “Modification design for the fan blade and the fixed-pitch propeller blade” are carried out to obtain the blade with the orientation structures. It should be pointed out that the performance of the orientation awls 10 will be slightly affected by the change of the pitch of the propeller, that is, the change of the angle of attack of the blade, which is specifically embodied as follows. The awl tips 11 in the cruising state that completely point to a tangential direction of a rotating direction are bound to be in a most efficient working condition since the orientation awls 10 are originally designed under the pitch lᵥ; and the efficacy of the awl tips 11 will reduce to some extent when working under an off-design pitch. However, the modified propeller 15 with the orientation awls 10 is more efficient and performing better than the criterial propeller even in this case.

In Step 3, an area of the pressure surface of the blade with the orientation awls 10 is accurately determined.

Scheme 1: For the Criterial Blade 1 with Known Design Parameters

The criterial blade 1 with the orientation awls 10 is stretched in the chord direction 5 to ensure an area of pressure surface of the stretched modified blade equal to the area of the pressure surface of the criterial blade 1, meanwhile the aerodynamic characteristics of the criterial propeller blade are able to be remained, which can be realized in the following ways.

(1) The area Aₘ_{₁} of the pressure surface of the blade with the orientation awls 10 is measured and recorded.

(2) A cylindrical coordinate system is established with an intersection between an axis of the rotational shaft 2 of the criterial blade 1 and the rotational plane of the criterial blade 1 as the pole O, the ray passing through the pole O on the rotational plane as the polar axis Ox, and the axis of the rotational shaft 2 of the criterial blade 1 that perpendicular to the rotational plane as the z-axis; the positive direction of the polar angle is the rotation direction of the propeller, and in the normal direction of the rotational plane, the positive direction of the z-axis is a direction that points from the pressure surface of the criterial blade 1 to the suction surface of the criterial blade 1; any point on the surface profile of the criterial blade 1 with the orientation awls 10 is expressed as (r, ψ, z) in cylindrical coordinates, where r, ψ, z represent the polar radius, the polar angle and the z-coordinate, respectively.

(3) An overall coordinate transformation is performed on all profile points directly into new profile points by programming according to the following rules: (r, ψ, z) is converted into

$$( r , ( ψ - {ψ}_{0} ) ( {t}_{1} {cos}^{2} θ + {sin}^{2} θ ) + \frac{z - {z}_{0}}{r} ( {t}_{1} - 1 ) sin θcos θ + {ψ}_{0} , r ( ψ - {ψ}_{0} ) sin θ cos θ ( {t}_{1} - 1 ) + ( z - {z}_{0} ) ( {t}_{1} {sin}^{2} θ + {cos}^{2} θ ) + {z}_{0} ) ,$$

by which a geometric significance is reflected, that is, a stretching in the overall chord direction to the blade is achieved by stretching each blade element at a multiple of t₁ in the chord direction 5 to obtain the modified blade. The angle of attack θ of the blade element and the tilt base point O of the chordwise section 3 where the profile points are located are both known in the conversion formula. θ is the angle of attack of the blade element of the chordwise section 3 where the profile points are located, and the tilt base point O (r, ψ₀, z₀) is the tilt base point of the chordwise section 3 where the profile points are located. θ depends on the radial twisting law of the blade and the radial positions of the profile points, which is a function of r. A position of the tilt base point O depends on the chord of the criterial blade 1 and the shape of the curve contour on the suction side of the criterial blade 1, and the tilt base point can be located by the curve equations of the contour of the criterial blade 1. Both of the value of θ and the position of point O will not change before and after the conversion. In the conversion formula, the chordwise stretching coefficient of the criterial blade 1 is

$${t}_{1} = \frac{{A}_{c}}{{A}_{{m}_{1}}} ,$$

A_{c} is an area of the pressure surface of the criterial blade 1. A blade enclosed by the new profile points is the blade which is stretched at a multiple of t₁ in its chord direction 5 on the basis of the criterial blade 1. The above coordinate conversion satisfies Aₘ_{₂}=t₁Aₘ=A_{c}, where Aₘ_{₂} is an area of a pressure surface of the single stretched blade.

### Scheme 2: The Scheme is the Same as the Scheme 2 in Step 5 in the Above-Mentioned “Modification Design for the Fan Blade and the Fixed-Pitch Propeller Blade”.

### Embodiment 2

This embodiment discloses a blade, which includes the orientation structures manufactured by the design method described in Embodiment 1.

### Embodiment 3

This embodiment discloses a performance test method for a propeller with the blade in Embodiment 2, that is, a universal theoretical basis for detecting the performance of the propeller and an experimental design example based on the theoretical basis are provided. Due to the need of this theoretical basis, a concept of “zero-thrust propeller” is introduced first, and its forming and manufacturing method is introduced.

### (1) Manufacturing Method for the Zero-Thrust Propeller

The zero-thrust propeller is a propeller based on a criterial propeller and possesses blades with a zero angle of attack. The zero-thrust propeller is manufactured by the following steps to retain the other geometric characteristics of the criterial propeller as much as possible, except of a characteristic of angle of attack of the blade element. The following method is also a universal method to change the angle of attack of the blade element of the propeller.

According to the different sources of criterial propellers, the manufacturing method for the zero-thrust propeller is classified into two schemes. The Scheme 1 is for the criterial blade 1 with known design parameters. The Scheme 2 is for the criterial blade 1 with unknown design parameters.

### Scheme 1

(1) The criterial propeller is taken. A cylindrical coordinate system is established with an intersection between an axis of a rotational shaft 2 of the criterial blade 1 and a rotational plane of the criterial blade 1 as a pole O, a ray passing through the pole O on the rotational plane as a polar axis Ox, and the axis of the rotational shaft 2 of the criterial blade 1 that perpendicular to the rotational plane as a z-axis. A positive direction of a polar angle is a rotation direction of the propeller, and in a normal direction of the rotational plane, a positive direction of the z-axis is a direction that points from the pressure surface of the criterial blade 1 to a suction surface of the criterial blade 1. In this way, any point on a surface profile of the propeller is expressed as (r, ψ, z) in cylindrical coordinates, where r, ψ, z represent a polar radius, the polar angle and the z-coordinate, respectively.

(2) Coordinates (r, ψ, z) of all profile points are converted according to the following rules by programming into

$$( r , ( ψ - {ψ}_{0} ) cos θ + \frac{z - {z}_{0}}{r} sin θ + {ψ}_{0} , ( z - {z}_{0} ) cos θ - r ( ψ - {ψ}_{0} ) sin θ + {z}_{0} ) ,$$

by which a geometric significance is reflected, that is, a propeller blade with a zero angle of attack is obtained by tilting each blade element by an angle (−θ) around its corresponding tilt base point O (r, ψ₀, z₀), in which the angle of attack θ of the blade element and the tilt base point O corresponding to each profile point are both known in the conversion formula. θ depends on the radial twisting law of the blade and the radial positions of the profile points, which is a function of r. The position of the tilt base point O depends on the chord of the blade and the shape of the curve contour on the suction side of the blade, and the tilt base point can be located by the curve equations of the contour of the blade. The position of the point O will not change before and after the conversion. A blade enclosed by the new profile points is the blade of a zero-thrust propeller based on the criterial propeller. The above coordinate conversion makes an area of the pressure surface of a single blade of the zero-thrust propeller still A_{c}.

### Scheme 2

(1) The criterial propeller is taken. A cylindrical coordinate system is established with an intersection between an axis of a rotational shaft 2 of the criterial blade 1 and a rotational plane of the criterial blade 1 as a pole O, a ray passing through the pole O on the rotational plane as a polar axis Ox, and the axis of the rotational shaft 2 of the criterial blade 1 that perpendicular to the rotational plane as a z-axis. A positive direction of a polar angle is a rotation direction of the propeller, and in a normal direction of the rotational plane, a positive direction of the z-axis is a direction that points from the pressure surface of the criterial blade 1 to the suction surface of the criterial blade 1.

(2) Chordwise sections 3 at all characteristic positions and several ordinary positions on the propeller blade are intercepted. The profile points of all characteristic positions and several ordinary positions are selected on each chordwise section 3. Coordinates of all profile points in the cylindrical coordinate system are marked. Generally, the coordinate of a certain profile point can be denoted as (r, ψ, z), where r, ψ, z represent a polar radius, the polar angle and the z-coordinate, respectively.

(3) The value of the angle of attack θ of the blade element corresponding to each chordwise section 3 is calculated by using the cylindrical coordinates of the points where a chord is tangent to the leading edge contour and the trailing edge contour.

(4) A tilt base point of each chordwise section 3 is specifically determined as follows. The chordwise section 3 which was originally a side of a cylinder is flattened, and a rectangular coordinate system with a generatrix intersecting a polar axis Ox on the side of the cylinder as a vertical axis and a straight line by flattening a circumference of bottom of the cylinder as a horizontal axis is established. An intersection O of a chord line AB and a thickness line OC on the chordwise section 3 is the tilt base point, as shown in FIG. 2. A rectangular coordinate of the point O is (rψ₀, z₀), and a cylindrical coordinate of the point O is (r, ψ₀, z₀).

(5) Each chordwise section 3 is tilted around the corresponding point O, such that the angle of attack of corresponding blade element is zero. Specifically, a coordinate transformation is performed on all profile points into new profile points to obtain coordinates of new profile points according to the following rules:

$$( r , ψ , z ) \to ( r , ( ψ - {ψ}_{0} ) cos θ + \frac{z - {z}_{0}}{r} sin θ + {ψ}_{0} , ( z - {z}_{0} ) cos θ - r ( ψ - {ψ}_{0} ) sin θ + {z}_{0} ) ,$$

in which the profile points with the same polar radius must correspond to the same angle of attack of the blade element and the tilt base point, and the tilt base point will not change before and after the conversion. All new profile points with the same polar radius are smoothly connected to form a new chordwise section to replace an original chordwise section 3, such that the original chordwise section 3 with the angle of attack θ of blade element is converted into a new chordwise section with a zero angle of attack of blade element by tilting around point O. Then all new chordwise sections are smoothly connected into a complete blade whose rotational radius is R, so as to form the zero-thrust propeller. An area of the pressure surface of a single blade of the zero-thrust propeller is still A_{c}.

It should be noted that, the zero-thrust propeller on the basis of a rationally designed criterial propeller indeed produce a thrust equal to zero. However, if a thrust produced by the zero-thrust propeller is not zero, the angle of attack of the pressure surface of each blade of the propeller can be fine-tuned to achieve a real zero-thrust output. Experiments are the final judgment on any account. During experiment, the so called zero-thrust means a thrust value fluctuates around zero, with a relatively small fluctuation amplitude.

### (2) Calculation Theory and its Process

This theoretical basis is based on the blade element theory, which studies the relationship between the propeller thrust, as well as the propeller aerodynamic drag and those propeller performance parameters. As shown in FIG. 12, an actual inflow with a speed of V_{N} acts on the pressure surface of the blade element, which results in a rebound flow in a speed of vᵢ that is perpendicular to the pressure surface of the blade element, where v; is referred to as induced speed. The pressure surface of the blade element could be functionally replaced by the action line 14 for pure aerodynamic impact on the pressure surface of the blade element. The propeller is assumed to rotate at a constant speed, vᵢ can be defined as follows:

$${v}_{i} = {μ}_{1} \cdot {V}_{N} sin ( θ - φ ) . \qquad ( 1 )$$

Where vᵢ is an induced velocity, μ₁ is a value between 0 and 1 that expresses the proportion of rebound flow in the direction of vᵢ arising directly from the pressure surface of the blade element; V_{N} is a velocity of actual inflow accepted by the N-th blade on the propeller; φ is an angle of the actual inflow relative to the propeller rotational plane, so as to obtain

$$φ = {tan}^{- 1} \frac{{v}_{c} + {μ}_{1} sin θ ( {μ}_{2} ω r cos θ + {v}_{c} sin θ )}{{μ}_{2} ω r + {μ}_{1} cos θ ( {μ}_{2} ω r cos θ + {v}_{c} sin θ )} . \qquad ( 2 )$$

Where v_{c} is the velocity of axial inflow; μ₂ is a deflection coefficient of the lateral inflow, μ₂>1; ψ is a rotational angular velocity of the propeller; for convenience, the angle of actual inflow φ is expressed as a function of the angle of attack θ of the blade element, that is, φ=g(θ), so as to obtain

$${V}_{N} = \frac{{μ}_{2} ω r}{cos g ( θ ) + {μ}_{1} sin [ θ - g ( θ ) ] sin θ} . \qquad ( 3 )$$

An aerodynamic force f(r) is expressed as:

$$f ( r ) = {K}_{1} \cdot \frac{1}{2} {ρ ( {V}_{N} sin α )}^{2} \cdot c \cdot dr \cdot sin α . \qquad ( 4 )$$

Where K₁ is a value greater than 1 that is applied to extend the aerodynamic impact force on the pressure surface of the blade element to a comprehensive aerodynamic force on the total blade element; ρ is a local air density; α is an included angle between the actual inflow and the action line 14 for pure aerodynamic impact on the pressure surface of the blade element; the angle of attack θ of the blade element and the chord length c of the blade element are expressed as functions of the radial position r where the blade element is located, that is, θ=h(r) and c=l(r), so as to obtain

$$f ( r ) = 2 {π}^{2} ρ {K}_{1} \cdot q ( r ) \cdot l ( r ) \cdot {n}^{2} \cdot {μ}_{2}^{2} \cdot {r}^{2} dr . \qquad ( 5 )$$

Where

$$q ( r ) = \frac{{sin}^{3} \{ h ( r ) - g [ h ( r ) ] \}}{{\{ cos g [ h ( r ) ] + {μ}_{1} sin \{ h ( r ) - g [ h ( r ) ] \} sinh ( r ) \}}^{2}} ,$$

n is a propeller rotational speed, a relationship between an angle β and the angle θ is established by using a deflection coefficient μ₃, where β is an included angle between the aerodynamic force f(r) and the axis of the rotational shaft 2 of the propeller, in which β=μ₃·h(r)=j(r), and the propeller thrust is expressed as:

$$\begin{matrix}T = {N}_{b} {\int }_{{r}_{0}}^{R} f ( r ) \cdot cos β \\ = 2 {π}^{2} {N}_{b} ρ {K}_{1} \cdot {μ}_{2}^{2} \cdot {n}^{2} {\int }_{{r}_{0}}^{R} q ( r ) \cdot l ( r ) \cdot cos j ( r ) \cdot {r}^{2} d r\end{matrix} . \qquad ( 6 )$$

Where N_{b} is the number of blades on the propeller, r₀ is the radial position of blade root on the propeller hub, and R is the rotational radius of the propeller. A zero-thrust propeller, which is based on an ordinary propeller but possesses blades with a zero angle of attack to theoretically produce no thrust, is introduced. The input power P₀ of the zero-thrust propeller is subtracted from the input power P of the ordinary propeller, such that the interference factors, such as the kinetic energy consumed by the moment of inertia of the propeller, and the resistance effect by the blade thickness and the airfoil, etc., can be effectively eliminated, such that a clear correlation between the input power difference of propellers and some known propeller parameters is established. The input power difference (P−P₀) of the propellers signifies the pure aerodynamic drag power of the propeller, so as to obtain

$$\begin{matrix}P - {P}_{0} = ω \cdot {N}_{b} {\int }_{{r}_{0}}^{R} f ( r ) \cdot sin β \cdot r \\ = 4 {π}^{3} {N}_{b} ρ {K}_{1} \cdot {μ}_{2}^{2} \cdot {n}^{3} {\int }_{{r}_{0}}^{R} q ( r ) \cdot l ( r ) \cdot sin j ( r ) \cdot {r}^{3} d r\end{matrix} . \qquad ( 7 )$$

The Formula (6) and the Formula (7) are purely theoretical formulae. After integration, each factor of the integrands in the Formula (6) and the Formula (7) is converted and expressed as follows: q(r) can be directly expressed as a dimensionless coefficient; l(r) is converted into the length of the characteristic chord c_{f}; h(r) is converted into a characteristic angle of attack θ_{w}, which is in a meaning of lift-to-drag angle as the cotangent function value of θ_{w} is the ratio of the thrust to the aerodynamic drag of the propeller; r is converted into a characteristic radius k_{f}R, which can be understood as an equivalent stressed spot of a blade. The dimensionless coefficient, c_{f}, θ_{w} and K_{f}R are substituted into the Formula (6) and the Formula (7) to obtain the following engineering formulae,

$$\{ \begin{matrix}T = K cos {θ}_{w} \cdot {c}_{f} {R}^{3} {n}^{2} \\ P - {P}_{0} = K sin {θ}_{w} \cdot 2 π {k}_{f} \cdot {c}_{f} {R}^{4} {n}^{3}\end{matrix} . \qquad ( 8 )$$

Where K is a propeller coefficient. The engineering formulae (8) have been corroborated by the experiment conducted by the inventor, more than that, and by a significant amount of open-source experimental data for other standard designed commercial propellers, where the thrust expression was directly verified, while the power difference expression was verified after the corresponding P₀ values for those standard designed propellers were estimated. Laws represented by the Formula (8) are followed by each rotating propeller, which is the basis for a performance verification experiment on the orientation structures in a convenient and economic way. Specifically, K mainly reflects the intensity of airstream engendered by the direct work by the propeller, and θ_{w} directly reflects the efficiency of the propeller for doing work, depending on the parallel of the wake path relative to the axis of the rotational shaft 2 of the propeller after the propeller action. Comprehensively, an aerodynamic coefficient K·cot θ_{w} is introduced as a more explicit metric that reflects both magnitude and direction, which is the main object of investigation in the experiment.

The above formulae can also serve for simulation after necessary adjustment. Since the simulation does not need the existence of any entity, and the propeller torque M has been sufficient to represent the aerodynamic drag torque, as a result, the pure aerodynamic drag power (P−P₀) is no longer necessary here, and naturally, modellings are only required for the two target propellers. The pure aerodynamic drag power expression for a propeller in the Formulae (8) is replaced by a propeller torque expression, to form the Formula (9) for simulation,

$$\{ \begin{matrix}T = K cos {θ}_{w} \cdot {c}_{f} {R}^{3} {n}^{2} \\ M = K sin {θ}_{w} \cdot {k}_{f} \cdot {c}_{f} {R}^{4} {n}^{2}\end{matrix} . \qquad ( 9 )$$

The criterial propeller and the modified propeller 15 (as shown in FIG. 13) are obtained according to the method in Embodiment 1, and the zero-thrust propeller is obtained according to the method in this embodiment. Thereafter, the superiority of the modified propeller 15 is tested by the on-ground test or the flight test. Specifically, in the aspect of experimental verification, the three propellers are driven by a suitable power system, and subsequently, the thrust value of each of the criterial propeller and the modified propeller 15 under a corresponding rotational speed value of each of the criterial propeller and the modified propeller 15, and a power source output power value of each of the criterial propeller, the modified propeller 15 and the zero-thrust propeller under the corresponding rotational speed value of each of the criterial propeller, the modified propeller 15 and the zero-thrust propeller, are recorded successively to obtain data arrays for the three propellers. After recording, the thrust value of each of the modified propeller 15 and the criterial propeller under the corresponding rotational speed value of each of the modified propeller 15 and the criterial propeller, a power difference value between the modified propeller 15 and the zero-thrust propeller under the corresponding rotational speed value of each of the modified propeller 15 and the zero-thrust propeller and a power difference value between the criterial propeller and the zero-thrust propeller under the corresponding rotational speed value of each of the criterial propeller and the zero-thrust propeller, are obtained, respectively. The aerodynamic coefficient K·cotθ_{w} of the modified propeller 15 and the aerodynamic coefficient K·cot θ_{w} of the criterial propeller are obtained by mathematical regression according to the Formulae (8) and are compared and analyzed.

In the aspect of simulation, a three-dimensional model of the criterial propeller and a three-dimensional model of the modified propeller 15 are obtained according to the method described in Embodiment 1. The thrust values and the torque values of the two propellers at several corresponding rotational speed points are set and recorded to obtain the data arrays for the two propellers. Thereafter, the aerodynamic coefficient K·cotθ_{w} of the modified propeller 15 and the aerodynamic coefficient K·cot θ_{w} of the criterial propeller are obtained by mathematical regression according to the Formulae (9) and are compared and analyzed.

Adaptive changes made according to actual needs fall within the scope of protection of the present disclosure.

It should be noted that it is obvious to those skilled in the art that the present disclosure is not limited to the details of the above-mentioned exemplary embodiments, and can be realized in other specific forms without departing from the spirit or basic characteristics of the present disclosure. Therefore, the embodiments should be considered in all aspects as illustrative and not restrictive. The scope of the present disclosure is defined by the appended claims rather than the above description, so that the scope is intended to embrace all changes that come within the meaning and range of equivalents of the claims in the present disclosure. Any reference numbers in the claims shall not be construed as limiting the claims concerned.

What is claimed is:

1. A design method for a blade with orientation structures,
for a criterial blade with known design parameters, the design method comprising:
S11, cutting materials at a trailing edge of the criterial blade from a fixed-pitch propeller to form orientation awls to obtain a modified blade, or cutting materials at a trailing edge of the criterial blade from a variable-pitch propeller under a pitch lᵥ in a cruising state to form orientation awls to obtain a modified blade; and
S12, stretching the blade with the orientation awls in a chord direction to obtain a modified blade, wherein an area of a pressure surface of the modified blade is equal to an area of a pressure surface of the criterial blade in Step S11; or
for a criterial blade with unknown design parameters, the design method comprising:
S21, first, calculating a chordwise stretching coefficient of the criterial blade according to an area of a pressure surface to be cut required for forming orientation awls;
S22, stretching the criterial blade in a chord direction according to the chordwise stretching coefficient to obtain a stretched blade; and
S23, cutting materials at a trailing edge of the stretched blade from a fixed-pitch propeller to form the orientation awls to obtain a modified blade, or cutting materials at a trailing edge of the stretched blade from a variable-pitch propeller under a pitch lᵥ in a cruising state to form the orientation awls to obtain a modified blade.

2. The design method for the blade with the orientation structures according to claim 1, wherein steps of formation of the orientation awls by cutting in Step S11 and Step S23 comprise:
from an axial perspective, creating (m+1) circular-arc awl-groove benchmark surfaces that are coaxial with a rotational shaft of the criterial blade and at equal intervals, wherein intersections between the (m+1) circular-arc awl-groove benchmark surfaces and the trailing edge of the criterial blade or the trailing edge of the stretched blade are awl tips of the orientation awls, a radius of one of the (m+1) circular-arc awl-groove benchmark surfaces with a smallest diameter is (1−σ)R, and an interval between adjacent circular-arc awl-groove benchmark surfaces of the (m+1) circular-arc awl-groove benchmark surfaces is μc_{f}; wherein m is an integer in a range
$$( \frac{σ R}{μ {c}_{f}} - 2 , \frac{σ R}{μ {c}_{f}} - 1 ] ,$$
R is a rotational radius of the criterial blade, c_{f} is a characteristic chord length of the criterial blade, μ is a ratio of the interval between the adjacent circular-arc awl-groove benchmark surfaces to the characteristic chord length of the criterial blade, and σ is a ratio of a radial length of a segment with the orientation awls in the criterial blade to the rotational radius R of the criterial blade; and
taking axial lines passing through the awl tips as rotational axes, a first circular-arc awl-groove benchmark surface of the (m+1) circular-arc awl-groove benchmark surfaces is rotated at an angle of γ-degree toward a blade tip, an (m+1)-th circular-arc awl-groove benchmark surface of the (m+1) circular-arc awl-groove benchmark surfaces is rotated at an angle of γ-degree toward a blade root, and each of circular-arc awl-groove benchmark surfaces between the first circular-arc awl-groove benchmark surface and the (m+1)-th circular-arc awl-groove benchmark surface is rotated at the angle of γ-degree toward the blade tip and is rotated at the angle of γ-degree toward the blade root to form an edge contour of the orientation awls; wherein a value of γ gradually decreases from the blade root to the blade tip.

3. The design method for the blade with the orientation structures according to claim 2, wherein σ has a value in a range of [−½, 1), μ has a value in a range of (0, ¼), and
$$\frac{R}{{c}_{f}} > 1 .$$

4. The design method for the blade with the orientation structures according to claim 2, wherein in Step S11 and Step S23, after obtaining the edge contour of the orientation awls, the design method further comprises:
blunting a connecting angle between adjacent two orientation awls of the orientation awls; wherein a process of blunting the connecting angle comprises: from the axial perspective, a center of a first arc where a first arc edge at one side, adjacent to the blade root, of the connecting angle is located is O₁, and a radius of the first arc is R₁, a center of a second arc where a second arc edge at an other side, away from the blade root, of the connecting angle is located is O₂, and a radius of the second arc is R₂, drawing a first circle with O₁ as a center and (R₁+R₃) as a radius, drawing a second circle with O₂ as a center and (R₂−R₃) as a radius, the first circle and the second circle intersect at a point O₃, and drawing a third circle with O₃ as a center and R₃ as a radius to obtain a blunting arc tangent to both the first arc edge and the second arc edge of the connecting angle; and
cutting the criterial blade along the edge contour of the orientation awls and a contour of the blunting arcs to obtain the blade with the orientation awls.

5. The design method for the blade with the orientation structures according to claim 4, wherein for the criterial blade from the fixed-pitch propeller with known design parameters, stretching the blade with the orientation awls in the chord direction to obtain the modified blade in Step S12 further comprises:
measuring and recording an area Aₘ_{₁} of the pressure surface of the blade with the orientation awls; establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; wherein a positive direction of a polar angle is a rotation direction of a propeller, and in a normal direction of the rotational plane, a positive direction of the z-axis is a direction that points from the pressure surface of the criterial blade to a suction surface of the criterial blade; any point on a surface profile of the blade with the orientation awls is able to be expressed as (r, ψ, z) in cylindrical coordinates, wherein r, ψ, z represent a polar radius, the polar angle and a z-coordinate, respectively; and
performing an overall coordinate transformation on all profile points directly into new profile points to obtain the modified blade according to following rules: converting (r, ψ, z) into
$$( r , ( ψ - {ψ}_{0} ) ( {t}_{1} {cos}^{2} θ + {t}_{2} {sin}^{2} θ ) + \frac{z - {z}_{0}}{r} ( {t}_{1} - {t}_{2} ) sin θ cos θ + {ψ}_{0} , r ( ψ - {ψ}_{0} ) sin θ cos θ ( {t}_{1} - {t}_{2} ) + ( z - {z}_{0} ) ( {t}_{1} {sin}^{2} θ + {t}_{2} {cos}^{2} θ ) + {z}_{0} ) ;$$
wherein the chordwise stretching coefficient of the criterial blade is
$${t}_{1} = \frac{{A}_{c}}{{A}_{{m}_{1}}} ,$$
A_{c} is tie area of the pressure surface of the criterial blade, t₂ is a stretching coefficient of the criterial blade in a thickness direction, and t₁>t₂>1, θ is an angle of attack of blade element of each of chordwise sections where profile points are located, and a tilt base point O (r, ψ₀, z₀) is a tilt base point of the chordwise section where the profile points are located.

6. The design method for the blade with the orientation structures according to claim 4, wherein for the criterial blade from the fixed-pitch propeller with unknown design parameters, a primary treatment is first performed, the primary treatment comprises:
scanning the criterial blade to obtain an external contour of the criterial blade;
establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; wherein a positive direction of a polar angle is a rotation direction of a propeller, and in a normal direction of the rotational plane, a positive direction of the z-axis is a direction that points from the pressure surface of the criterial blade to a suction surface of the criterial blade; and
taking chordwise sections at all characteristic positions and several ordinary positions on the criterial blade which represent an overall contour of the criterial blade, and selecting points at all characteristic positions and several ordinary positions on each of the chordwise sections which represent an overall contour of each of the chordwise sections, and expressing the points as (r, ψ, z) in cylindrical coordinates; wherein r, ψ, z represent a polar radius, the polar angle and a z-coordinate, respectively; wherein in Step S21, the chordwise stretching coefficient of the criterial blade is
$${t}_{1} = 1 + \frac{{A}_{c u t}}{{A}_{c}} ,$$
wherein A_{c} is the area of the pressure surface of the criterial blade, A_{cut} is an area of a pressure surface to be cut required for forming the orientation awls; and
converting the cylindrical coordinates (r, ψ, z) of points on the overall contour of each of the chordwise sections after performing the primary treatment into
$$( r , ( ψ - {ψ}_{0} ) ( {t}_{1} {cos}^{2} θ + {t}_{2} {sin}^{2} θ ) + \frac{z - {z}_{0}}{r} ( {t}_{1} - {t}_{2} ) sin θ cos θ + {ψ}_{0} , r ( ψ - {ψ}_{0} ) sin θ cos θ ( {t}_{1} - {t}_{2} ) + ( z - {z}_{0} ) ( {t}_{1} {sin}^{2} θ + {t}_{2} {cos}^{2} θ ) + {z}_{0} )$$
to obtain the stretched blade; wherein t₂ is a stretching coefficient of the criterial blade in a thickness direction, t₁>t₂>1, θ is an angle of attack of blade element of each of the chordwise sections where profile points are located, a tilt base point O (r, ψ₀, z₀) is a tilt base point of the chordwise section where the profile points are located, and a value of θ and a cylindrical coordinate of a point O are calculated by using the cylindrical coordinates of points where a chord is tangent to a leading edge contour and a trailing edge contour.

7. The design method for the blade with the orientation structures according to claim 5, wherein for the criterial blade with a fixed pitch, the design method further comprises: forming m orientation grooves on a back of the modified blade on a basis of curves intersected between the m circular-arc awl-groove benchmark surfaces and the back of the modified blade, so as to make each of the curves be a bottom of a corresponding orientation groove of the m orientation grooves; wherein the m orientation grooves locate at a blade segment from a second circular-arc awl-groove benchmark surface to the (m+1)-th circular-arc awl-groove benchmark surface; each of the m orientation grooves is an arc groove with a groove depth of d, which satisfies d=λ·δₘ₋₁, wherein δₘ₋₁ is a blade thickness on the chordwise section where a bottom curve of an (m−1)-th orientation groove of the m orientation grooves is located, λ has a value in a range of (0, ½); a same one of the m orientation grooves has a same arc radius ρ, arc radii ranging from ρ₁ to ρₘ of the m orientation grooves gradually increase from the blade root to the blade tip to form an arithmetic progression with a first term of ρ₁ and a tolerance of
$$\frac{{ρ}_{m} - {ρ}_{1}}{m - 1} , wherein d < {ρ}_{1} < {ρ}_{m} < \frac{{μ}^{2} {c}_{f}^{2}}{8 d} + \frac{d}{2} .$$

8. The design method for the blade with the orientation structures according to claim 6, wherein for the criterial blade with a fixed pitch, the design method further comprises: forming m orientation grooves on a back of the modified blade on a basis of curves intersected between the m circular-arc awl-groove benchmark surfaces and the back of the modified blade, so as to make each of the curves be a bottom of a corresponding one orientation groove of the m orientation grooves; wherein the m orientation grooves locate at a blade segment from a second circular-arc awl-groove benchmark surface to the (m+1)-th circular-arc awl-groove benchmark surface; each of the m orientation grooves is an arc groove with a groove depth of d, which satisfies d=λ·δₘ₋₁, wherein δₘ₋₁ is a blade thickness on the chordwise section where a bottom curve of an (m−1)-th orientation groove of the m orientation grooves is located, λ has a value in a range of (0, ½); a same one of the m orientation grooves has a same arc radius ρ, arc radii ranging from ρ₁ to ρₘ of the m orientation grooves gradually increase from the blade root to the blade tip to form an arithmetic progression with a first term of ρ₁ and a
tolerance of
$$\frac{{ρ}_{m} - {ρ}_{1}}{m - 1} , wherein d < {ρ}_{1} < {ρ}_{m} < \frac{{μ}^{2} {c}_{f}^{2}}{8 d} + \frac{d}{2} .$$

9. The design method for the blade with the orientation structures according to claim 4, wherein for the criterial blade from the variable-pitch propeller with known design parameters, stretching the blade with the orientation awls in the chord direction to obtain the modified blade in Step S12 further comprises:
measuring and recording an area Aₘ_{₁} of the pressure surface of the blade with the orientation awls; establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; wherein a positive direction of a polar angle is a rotation direction of a propeller, and in a normal direction of the rotational plane, a positive direction of the z-axis is a direction that points from the pressure surface of the criterial blade to a suction surface of the criterial blade; any point on a surface profile of the blade with the orientation awls is able to be expressed as (r, ψ, z) in cylindrical coordinates, wherein r, ψ, z represent a polar radius, the polar angle and a z-coordinate, respectively; and
performing an overall coordinate transformation on all profile points directly into new profile points to obtain the modified blade according to following rules: converting (r, ψ, z) into
$$( r , ( ψ - {ψ}_{0} ) ( {t}_{1} {cos}^{2} θ + {sin}^{2} θ ) + \frac{z - {z}_{0}}{r} ( {t}_{1} - 1 ) sin θ cos θ + {φ}_{0} , r ( ψ - {ψ}_{0} ) sin θ cos θ ( {t}_{1} - 1 ) + ( z - {z}_{0} ) ( {t}_{1} {sin}^{2} θ + {cos}^{2} θ ) + {z}_{0} ) ;$$
wherein the chordwise stretching coefficient of the criterial blade is
$${t}_{1} = \frac{{A}_{c}}{{A}_{{m}_{1}}} ,$$
A_{c} is the area of the pressure surface of the criterial blade, θ is an angle of attack of blade element of each of chordwise sections where profile points are located, and a tilt base point O (r, ψ₀, z₀) is a tilt base point of the chordwise section where the profile points are located.

10. The design method for the blade with the orientation structures according to claim 4, wherein for the criterial blade from the variable-pitch propeller with unknown design parameters, a primary treatment is first performed, the primary treatment comprises:
scanning the criterial blade to obtain an external contour of the criterial blade;
establishing a cylindrical coordinate system with an intersection between an axis of the rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; wherein a positive direction of a polar angle is a rotation direction of a propeller, and in a normal direction of the rotational plane, a positive direction of the z-axis is a direction that points from the pressure surface of the criterial blade to a suction surface of the criterial blade; and
taking chordwise sections at all characteristic positions and several ordinary positions on the criterial blade which represent an overall contour of the criterial blade, and selecting points at all characteristic positions and several ordinary positions on each of the chordwise sections which represent an overall contour of each of the chordwise sections, and expressing the points as (r, ψ, z) in cylindrical coordinates; wherein r, ψ, z represent a polar radius, the polar angle and a z-coordinate, respectively; wherein in Step S21, the chordwise stretching coefficient of the criterial blade is
$${t}_{1} = 1 + \frac{{A}_{c u t}}{{A}_{c}} ,$$
wherein A_{c} is the area of the pressure surface of the criterial blade, A_{cut} is an area of a pressure surface to be cut required for forming the orientation awls; and
converting the cylindrical coordinates (r, ψ, z) of points on the overall contour of each of the chordwise sections after performing the primary treatment into
$$( r , ( ψ - {ψ}_{0} ) ( {t}_{1} {cos}^{2} θ + {sin}^{2} θ ) + \frac{z - {z}_{0}}{r} ( {t}_{1} - 1 ) sin θ cos θ + {ψ}_{0} , \\ r ( ψ - {ψ}_{0} ) sin θ cos θ ( {t}_{1} - 1 ) + ( z - {z}_{0} ) ( {t}_{1} {sin}^{2} θ + {cos}^{2} θ ) + {z}_{0} )$$
to obtain the stretched blade; wherein θ is an angle of attack of blade element of each of the chordwise sections where profile points are located, a tilt base point O (r, ψ₀, z₀) is a tilt base point of the chordwise section where the profile points are located, and a value of θ and a cylindrical coordinate of a point O are calculated by using the cylindrical coordinates of points where a chord is tangent to a leading edge contour and a trailing edge contour.

11. A blade with orientation structures, wherein the blade is manufactured according to the design method for the blade with the orientation structures according to claim 1.

12. A performance test method for the blade with the orientation structures according to claim 11, comprising:
S1, manufacturing a zero-thrust propeller, wherein an angle of attack of each blade of the zero-thrust propeller is 0; each blade of the zero-thrust propeller is obtained by each blade element of the criterial blade tilting an angle of (−θ) around a corresponding tilt base point O (r, ψ₀, z₀);
S2, performing calculation according to following formulae:
$${v}_{i} = {μ}_{1} \cdot {V}_{N} sin ( θ - φ ) \qquad ( 1 )$$
wherein vᵢ is an induced velocity, μ₁ is a value between 0 and 1 that expresses proportion of rebound flow in a direction of vᵢ arising directly from a pressure surface of the blade element; V_{N} is a velocity of actual inflow for a N-th blade on a common propeller that is a modified propeller or a criterial propeller; and φ is an angle of the actual inflow relative to a rotational plane of the common propeller, so as to obtain
$$φ = {tan}^{- 1} \frac{{v}_{c} + {μ}_{1} sin θ ( {μ}_{2} ω r cos θ + {v}_{c} sin θ )}{{μ}_{2} ω r + {μ}_{1} cos θ ( {μ}_{2} ω r cos θ + {v}_{c} sin θ )} \qquad ( 2 )$$
wherein v_{c} is a velocity of axial inflow; μ₂ is a deflection coefficient of the lateral inflow, and μ₂>1; ω is a rotational angular velocity of the common propeller; and φ is an angle of the actual inflow and is expressed as a function of an angle of attack θ of the blade element, that is, φ=g(θ), so as to obtain
$${V}_{N} = \frac{{μ}_{2} ω r}{cos g ( θ ) + {μ}_{1} sin [ θ - g ( θ ) ] sin θ} \qquad ( 3 )$$
an aerodynamic force f(r) is expressed as:
$$f ( r ) = {K}_{1} \cdot \frac{1}{2} {ρ ( {V}_{N} sin α )}^{2} \cdot c \cdot dr \cdot sin α \qquad ( 4 )$$
wherein K₁ is a coefficient that is applied to extend an aerodynamic impact force on the pressure surface of the blade element to a comprehensive aerodynamic force on a total blade element, and K₁ is greater than 1; μ is local air density; α is an included angle between the actual inflow and an action line for pure aerodynamic impact on the pressure surface of the blade element; the angle of attack θ of the blade element and a chord length c of the blade element are expressed as functions of a radial position r where the blade element is located, that is, θ=h(r), and c=l(r), so as to obtain
$$f ( r ) = 2 {π}^{2} ρ {K}_{1} \cdot q ( r ) \cdot l ( r ) \cdot {n}^{2} \cdot {μ}_{2}^{2} \cdot {r}^{2} d r \qquad ( 5 )$$
wherein
$$q ( r ) = \frac{{sin}^{3} \{ h ( r ) - g [ h ( r ) ] \}}{{\{ cos g [ h ( r ) ] + {μ}_{1} sin \{ h ( r ) - g [ h ( r ) ] \} sin h ( r ) \}}^{2}} , n$$
is a propeller rotational speed, a relationship between an angle β and the angle of attack θ of the blade element is established by using a deflection coefficient μ₃, wherein β is an included angle between the aerodynamic force f(r) and an axis of rotational shaft of the common propeller, in which β=μ₃·h(r)=j(r), and propeller thrust is expressed as:
$$T = {N}_{b} {\int }_{{r}_{0}}^{R} f ( r ) \cdot cos β = 2 {π}^{2} {N}_{b} ρ {K}_{1} \cdot {μ}_{2}^{2} \cdot {n}^{2} {\int }_{{r}_{0}}^{R} q ( r ) \cdot l ( r ) \cdot cos j ( r ) \cdot {r}^{2} d r \qquad ( 6 )$$
wherein N_{b} is a number of blades on the common propeller, r₀ is a radial position of a blade root on a propeller hub, and R is a rotational radius of the common propeller; an input power P₀ of the zero-thrust propeller is subtracted from an input power P of the modified propeller or the criterial propeller, and a pure aerodynamic drag power of the common propeller is expressed as:
$$P - {P}_{0} = ω \cdot {N}_{b} {\int }_{{r}_{0}}^{R} f ( r ) \cdot sin β \cdot r = 4 {π}^{3} {N}_{b} ρ {K}_{1} \cdot {μ}_{2}^{2} \cdot {n}^{3} {\int }_{{r}_{0}}^{R} q ( r ) \cdot l ( r ) \cdot sin j ( r ) \cdot {r}^{3} d r \qquad ( 7 )$$
after integration, each factor of integrands in a formula (7) is transformed and is expressed as follows: q(r) is directly expressed as a dimensionless coefficient; l(r) is converted into a length of a characteristic chord c_{f}; h(r) is converted into a characteristic angle of attack θ_{w}, and r is converted into a characteristic radius K_{f}R; making the dimensionless coefficient, c_{f}, θ_{w} and K_{f}R substitute into a formula (6) and the formula (7) to obtain following engineering formulae:
$$\{ \begin{matrix}T = K cos {θ}_{w} \cdot {c}_{f} {R}^{3} {n}^{2} \\ P - {P}_{0} = K sin {θ}_{w} \cdot 2 π {k}_{f} \cdot {c}_{f} {R}^{4} {n}^{3}\end{matrix} \qquad ( 8 )$$
wherein K is a propeller coefficient; on a basis of the engineering formulae (8), the pure aerodynamic drag power (P−P₀) of the common propeller is replaced by a propeller torque M, and calculation formulae for simulation is:
$$\{ \begin{matrix}T = K cos {θ}_{w} \cdot {c}_{f} {R}^{3} {n}^{2} \\ M = K sin {θ}_{w} \cdot {k}_{f} \cdot {c}_{f} {R}^{4} {n}^{2}\end{matrix} \qquad ( 9 )$$
in an aspect of experimental verification, the criterial propeller with criterial blades, the modified propeller whose blades are modified by the orientation structures, and the zero-thrust propeller are driven by an identical power source, and a thrust value of each of the criterial propeller and the modified propeller under a corresponding rotational speed value of each of the criterial propeller and the modified propeller, and a power source output power value of each of the criterial propeller, the modified propeller and the zero-thrust propeller under the corresponding rotational speed value of each of the criterial propeller, the modified propeller and the zero-thrust propeller, are recorded successively to obtain data arrays for the criterial propeller, the modified propeller and the zero-thrust propeller; after recording, the thrust value of each of the modified propeller and the criterial propeller under the corresponding rotational speed value of each of the modified propeller and the criterial propeller, a power difference value between the modified propeller and the zero-thrust propeller under the corresponding rotational speed value of each of the modified propeller and the zero-thrust propeller, and a power difference value between the criterial propeller and the zero-thrust propeller under the corresponding rotational speed value of each of the criterial propeller and the zero-thrust propeller, are obtained, respectively; an aerodynamic coefficient K·cot θ_{w} of the modified propeller and an aerodynamic coefficient K·cot θ_{w} of the criterial propeller are obtained according to the engineering formulae (8) and are compared and analyzed;
in the aspect of simulation, a three-dimensional model of the criterial propeller and a three-dimensional model of the modified propeller are obtained, and thrust values and torque values of the criterial propeller and the modified propeller at several corresponding rotational speed values are set and recorded to obtain data arrays for the criterial propeller and the modified propeller; an aerodynamic coefficient K·cotθ_{w} of the modified propeller and an aerodynamic coefficient K·cotθ_{w} of the criterial propeller are obtained according to the calculation formulae (9) and are compared and analyzed.

13. The performance test method for the blade with the orientation structures according to claim 12, wherein for the criterial blade with known design parameters, the zero-thrust propeller is manufactured by a following method, comprising:
taking the criterial blade, establishing a cylindrical coordinate system with an intersection between an axis of a rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; wherein the positive direction of a polar angle is a rotation direction of the common propeller, and in a normal direction of the rotational plane, the positive direction of the z-axis is a direction that points from the pressure surface of the criterial blade to a suction surface of the criterial blade; any point on a profile of the criterial blade is expressed as (r, ψ, z) in cylindrical coordinates, wherein r, ψ, z represent a polar radius, the polar angle and a z-coordinate, respectively; and
performing an overall coordinate transformation on all profile points directly into new profile points to obtain a blade contour of the zero-thrust propeller according to following rules:
$$( r , ( ψ - {ψ}_{0} ) cos θ + \frac{z - {z}_{0}}{r} sin θ + {ψ}_{0} , ( z - {z}_{0} ) cos θ - r ( ψ - {ψ}_{0} ) sin θ + {z}_{0} ) .$$

14. The performance test method for the blade with the orientation structures according to claim 12, wherein for the criterial blade with unknown design parameters, a zero-thrust propeller is manufactured by a following method, comprising:
taking the criterial blade, establishing a cylindrical coordinate system with an intersection between an axis of a rotational shaft of the criterial blade and a rotational plane of the criterial blade as a pole, a ray passing through the pole on the rotational plane as a polar axis, and the axis of the rotational shaft of the criterial blade that perpendicular to the rotational plane as a z-axis; wherein a positive direction of the polar angle is a rotation direction of the common propeller, and in a normal direction of the rotational plane, a positive direction of the z-axis is a direction that points from the pressure surface of the criterial blade to a suction surface of the criterial blade; and
taking chordwise sections at all characteristic positions and several ordinary positions on the criterial blade which represent an overall contour of the criterial blade, and selecting points at all characteristic positions and several ordinary positions on each of the chordwise sections which represent an overall contour of each of the chordwise sections, and expressing the points as (r, ψ, z) in cylindrical coordinates; wherein r, ψ, z represent a polar radius, the polar angle and a z-coordinate, respectively;
calculating a value of the angle of attack θ of the blade element corresponding to each of the chordwise sections by using the cylindrical coordinates of points where a chord is tangent to a leading edge contour and a trailing edge contour;
determining a rectangular coordinate of a tilting base point O of each of the chordwise sections as (rψ₀, z₀) and the cylindrical coordinate of the tilting base point O of each of the chordwise sections as (r, ψ₀, z₀);
tilting each of the chordwise sections around a corresponding tilting base point O to make the angle of attack of a corresponding blade element zero;
performing a coordinate transformation on all profile points to obtain coordinates of new profile points according to following rules: converting (r, ψ, z) into
$$( r , ( ψ - {ψ}_{0} ) cos θ + \frac{z - {z}_{0}}{r} sin θ + {ψ}_{0} , ( z - {z}_{0} ) cos θ - r ( ψ - {ψ}_{0} ) sin θ + {z}_{0} ) ;$$
smoothly connecting all the new profile points with a same polar radius into new chordwise sections; and
smoothly connecting all the new chordwise sections into a complete blade whose rotational radius is R to obtain a blade profile of the zero-thrust propeller.
